(19) United States
(12) Patent Application Publication
(10) Pub. No.: US 2026/0354246 A1
(43) Pub. Date: Nov. 5, 2026

(54) POLYMER, PHOTOSENSITIVE RESIN COMPOSITION CONTAINING SAME, COPPER PASTE, LIQUID COMPOSITION, METHOD FOR PRODUCING SEMICONDUCTOR DEVICE, AND METHOD FOR PRODUCING COPPER PILLAR FOR SEMICONDUCTOR CONNECTION

(71) Applicant: Daicel Corporation, Osaka-shi, Osaka (JP)

(72) Inventors: Kouichi TAKAWAKI, Tokyo (JP); Rumi NAGAI, Tokyo (JP); Tadashi TERANISHI, Tokyo (JP); Akihiko HAPPOYA, Tokyo (JP); Hirokatsu SAKAMOTO, Tokyo (JP); Akio SHIMOYAMA, Tokyo (JP); Takanori KOBATAKE, Tokyo (JP)

(73) Assignee: Daicel Corporation, Osaka-shi, Osaka (JP)

(21) Appl. No.: 19/486,006

(22) PCT Filed: May 30, 2024
(86) PCT No.: PCT/JP2024/019804

§ 371 Date: Nov. 19, 2025

(30) Foreign Application Priority Data
May 30, 2023 (JP) 2023-088938

(51) Int. Cl. H10W 72/20; C08F 20/18; H10W 72/00

(52) U.S. Cl. CPC H10W 72/252; C08F 20/18; H10W 72/01265

(57) ABSTRACT

Provided is a method for producing a semiconductor device, the method including: preparing a structure, including forming a resin layer on a substrate or a semiconductor chip using a resin composition, and patterning the resin layer to form a patterned resin layer including an opening; and bonding two or more of the structures using the patterned resin layer.

### TECHNICAL FIELD

The present embodiments relate to a polymer, a photosensitive resin composition containing the same, a copper paste, a liquid composition, a method for producing a semiconductor device, and a method for producing a copper pillar for semiconductor connection.

### BACKGROUND ART

With the advent of post 5G and 6G societies, there is a rapidly increasing demand for advanced technologies for semiconductors that transmit a huge amount of information at high speed with low latency in all hardware from communication infrastructures to edge devices such as smartphones and tablet terminals. Miniaturization and an increase in the number of connection terminals in accordance with high integration of semiconductors are required for realizing such technologies. In a production process, not only miniaturization processing in a pre-step but also a package mounting technique for three dimensionally integrating a plurality of semiconductors in a post-step is becoming increasingly important.

Severe process conditions of high temperature and high pressure are required for copper pillar bonding in connection between semiconductor chips. Further progress in copper-copper direct bonding technique is required for realization of further miniaturization.
Patent Document 1: JP 2021-197430 A

### SUMMARY OF INVENTION

(1) Many steps are required for known production of a semiconductor device, due to miniaturization and an increase in the number of connection terminals in accordance with high integration of semiconductors.

A first object of the present disclosure is to provide a method for producing a semiconductor device, which can include a reduced number of steps as compared with the related art.

(2) In connection between semiconductor chips, a narrower pitch of metal pillars is required from the viewpoint of higher density, and, in addition, a resist resin capable of being patterned at a narrow pitch is also required.

A second object of the present disclosure is to provide a polymer (A) capable of being patterned at a narrower pitch, and a photosensitive resin composition containing the same.

(3) In a known method of patterning with a resist resin and forming a pillar by copper plating, the number of steps for forming the pillar is large. In addition, in order to bond the pillars formed by copper plating to each other through copper-copper bonding, process conditions of a high temperature of from 300 to 400 °C and a high pressure are required.

A third object of the present disclosure is to provide a copper paste that can reduce the number of steps for forming a copper pillar and lower a bonding temperature as compared with the related art. Another object of the present disclosure is to provide a copper paste having excellent fillability even when a resist opening formed on a semiconductor chip is narrow.

(4) For known bonding of the pillars formed by copper plating to each other through copper-copper bonding as described above, process conditions of a high temperature of from 300 to 400 °C and a high pressure are required. When the bonding temperature is high, there is a possibility that cracks and bonding defects may occur due to the influence of thermal stress caused by warpage of a substrate and a difference in linear expansion coefficients between different materials.

A fourth object of the present disclosure is to provide a liquid composition capable of lowering a bonding temperature as compared with the related art.

As a result of intensive studies, (1) the present inventors have found that the first object can be achieved by a method for producing a semiconductor device, the method including:
preparing a structure, including
forming a resin layer on a substrate or a semiconductor chip using a resin composition, and
patterning the resin layer to form a patterned resin layer including an opening; and
bonding two or more of the structures using the patterned resin layer.

(2) The present inventors have found that the second object can be achieved by a polymer (A) for producing a resin composition in a method for producing a semiconductor device, the polymer (A) including monomer units (A1) and (A2) below.

(3) The present inventors have found that the third object can be achieved by a copper paste for producing a copper pillar for semiconductor connection, containing:
copper particles; and
a dispersion medium containing a basic compound and a reducing organic substance,
wherein a molar ratio of a basic group contained in the basic compound to an acidic group contained in the reducing organic substance (basic group/acidic group) is from 0.5 to 1.2, and a viscosity at 25 °C and a shear rate of 10 s⁻¹ as measured by a rheometer is from 0.1 to 200 Pa·s.

(4) The present inventors have found that the fourth object can be achieved by a liquid composition for assisting in bonding of pillars for semiconductor connection to each other, the liquid composition containing: a reducing organic substance; a basic compound; and a coordinating organic compound excluding a compound included in the basic compound, wherein the coordinating organic compound has a boiling point higher than that of the reducing organic substance.

### BRIEF DESCRIPTION OF DRAWINGS

FIG. 1 shows an electron micrograph image of a surface of a solvent-treated copper foil of Example 16.

FIG. 2 shows an electron micrograph image of a surface of a solvent-treated copper foil of Example 17.

FIG. 3 shows an electron micrograph image of a surface of a solvent-treated copper foil of Comparative Example 9.

FIG. 4 shows an electron micrograph image of an arrangement pattern of an Si chip with copper bumps used in Example 29.

FIG. 5 shows an electron micrograph image of a surface of a copper bump portion of the Si chip with copper bumps used in Example 29.

FIG. 6 shows an electron micrograph image of a surface of a copper bump portion of a solvent-treated Si chip of Example 29.

FIG. 7 is a cross-sectional SEM image of a bonded body of Example 30.

FIG. 8 is an enlarged view of FIG. 7.

FIG. 9 is a cross-sectional SEM image of a bonded body of Example 31.

FIG. 10 is an enlarged view of FIG. 9.

### DESCRIPTION OF EMBODIMENTS

The present embodiments include the following aspects.

### First Embodiment

[1]A method for producing a semiconductor device, the method including:
preparing a structure, including
forming a resin layer on a substrate or a semiconductor chip using a resin composition, and
patterning the resin layer to form a patterned resin layer including an opening; and
bonding two or more of the structures using the patterned resin layer.

[2] The method for producing a semiconductor device according to [1], wherein the resin composition is a photosensitive resin composition, and the patterning is performed by exposure and development.

[3] The method for producing a semiconductor device according to [1] or [2], wherein a pitch of the adjacent openings is 80 μm or less.

[4] The method for producing a semiconductor device according to any one of [1] to [3], wherein an opening width of the opening is less than 40 μm.

[5] The method for producing a semiconductor device according to any one of [1] to [4], wherein the preparation includes producing a metal pillar in the opening.

[6] The method for producing a semiconductor device according to [5], wherein the producing a metal pillar includes filling the opening with a copper paste,
the copper paste contains copper particles and a dispersion medium containing a basic compound and a reducing organic substance, and
a molar ratio of a basic group contained in the basic compound to an acidic group contained in the reducing organic substance (basic group/acidic group) is from 0.5 to 1.2.

[7] The method for producing a semiconductor device according to [5] or [6], further including: planarizing a surface where the metal pillar and a pattern of the patterned resin layer exist, prior to the bonding.

[8] The method for producing a semiconductor device according to [7], wherein the planarization is performed by CMP.

[9] The method for producing a semiconductor device according to any one of [5] to [8], wherein the bonding includes bonding two or more of the structures at a temperature of 200 °C or higher and 250 °C or lower with the metal pillars of the respective structures overlapping each other.

[10] The method for producing a semiconductor device according to any one of [5] to [9], wherein the bonding includes bonding two or more of the structures at a temperature of lower than 200 °C with the metal pillars of the respective structures overlapping each other.

[11] The method for producing a semiconductor device according to any one of [5] to [10], further including applying a liquid composition to a bonding portion of the metal pillar before the bonding.

[12] The method for producing a semiconductor device according to [11], wherein the liquid composition contains a reducing organic substance, a basic compound, and a coordinating organic compound excluding a compound included in the basic compound, and the coordinating organic compound has a boiling point higher than that of the reducing organic substance.

[13] The method for producing a semiconductor device according to any one of [1] to [12], wherein the resin layer is formed using a polymer (A) including monomer units (A1) and (A2) below:
a monomer unit (A1): a monomer having an alkali-soluble group,
a monomer unit (A2): an aromatic (meth)acrylate having a phenolic hydroxyl group.

### Second Embodiment

[14]A polymer (A) for producing the resin composition in a method for producing a semiconductor device, particularly, the method for producing a semiconductor device described in any one of [1] to [12], the polymer (A) containing monomer units (A1) and (A2) below:
a monomer unit (A1): a monomer having an alkali-soluble group,
a monomer unit (A2): an aromatic (meth)acrylate having a phenolic hydroxyl group.

[15] The polymer (A) according to [14], further containing a monomer unit (A3): an N-substituted maleimide compound.

[16] The polymer (A) according to [14] or [15], further containing a monomer unit (A4): an alkyl (meth)acrylate having an alkyl group with 2 or more carbon atoms.

[17] The polymer (A) according to any one of [14] to [16], wherein a proportion of the monomer unit (A1) to a total amount (100 mol %) of all the monomer units constituting the polymer (A) is from 5 to 50 mol %.

### Third Embodiment

[18]A photosensitive resin composition for a method for producing a semiconductor device, particularly, the method for producing a semiconductor device described in any one of [1] to [12], the photosensitive resin composition containing:
a polymer (A) containing monomer units (A1) and (A2) below:
a monomer unit (A1): a monomer having an alkali-soluble group,
a monomer unit (A2): an aromatic (meth)acrylate having a phenolic hydroxyl group;
a photopolymerization initiator (B); and
a solvent (C).

### Fourth Embodiment

[19]A copper paste for producing a copper pillar for semiconductor connection, the copper paste containing:
copper particles; and
a dispersion medium containing a basic compound and a reducing organic substance,
wherein a molar ratio of a basic group contained in the basic compound to an acidic group contained in the reducing organic substance (basic group/acidic group) is from 0.5 to 1.2, and a viscosity at 25 °C and a shear rate of 10 s⁻¹ as measured by a rheometer is from 0.1 to 200 Pa·s.

[20] The copper paste according to [19], wherein the basic compound is a nitrogen-containing compound represented by Formula (1) below:

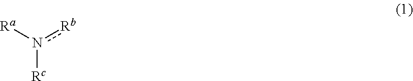

wherein R^{a} to R^{c} are the same or different and each represent a hydrogen atom or a hydrocarbon group optionally having a substituent; the substituents are the same or different and are each at least one group selected from an amino group, an N-substituted amino group, an N,N-substituted amino group, an imino group, an N-substituted imino group, and a hydroxyl group, provided that R^{a} to R^{c} are not hydrogen atoms at the same time; a double line including a broken line represents a single bond or a double bond, and in the case of a double bond, R^{c} is not present; and any two of R^{a} to R^{c} may bond to each other and form a ring together with an adjacent nitrogen atom.

[21] The copper paste according to [19] or [20], wherein the reducing organic substance is at least one organic substance selected from formic acid and oxalic acid.

[22] The copper paste according to any one of [19] to [21], wherein the viscosity at 25 °C and a shear rate of 10 s⁻¹ as measured by a rheometer is 0.1 Pa·s or more and less than 100 Pa·s.

[23] The copper paste according to any one of [19] to [22], wherein a maximum peak temperature of differential thermogravimetric analysis (DTG) at a temperature rising rate of 10 °C/min in a nitrogen atmosphere is from 100 to 220 °C.

[24] The copper paste according to any one of [19] to [23], wherein the copper particles have a volume average particle size of 1 nm or more and 500 nm or less.

[25] The copper paste according to any one of [19] to [24], wherein a content of the copper particles in the copper paste is from 50 to 85 mass %.

[26] The copper paste according to any one of [19] to [25], wherein a content of the reducing organic substance in the copper paste is from 6.0 to 22.0 wt. %, and a content of the basic compound is from 3.0 to 35.0 wt. %.

[27] The copper paste according to any one of [19] to [26], wherein a content of the basic compound is from 3.0 to 35.0 wt. %, and a weight ratio of the basic compound to the reducing organic substance (basic compound/reducing organic substance) is from 0.4 to 5.0.

### Fifth Embodiment

[28]A method for producing a semiconductor device, the method including:
forming a resin layer on a substrate or a semiconductor chip using a resin composition;
patterning the resin layer to form a patterned resin layer including an opening; and
filling the opening with a copper paste, particularly, the copper paste described in any one of [19] to [27], to form a copper pillar.

[29] The method for producing a semiconductor device according to [28], further including bonding the copper pillars to each other after removing the patterned resin layer.

[30] The method for producing a semiconductor device according to [28], further including:
bonding the patterned resin layers to each other without removing the patterned resin layers; and
metal-bonding the copper pillars to each other.

[31] Use of a copper paste for producing a copper pillar for semiconductor connection, the copper paste containing:
copper particles; and
a dispersion medium containing a basic compound and a reducing organic substance,
wherein a molar ratio of a basic group contained in the basic compound to an acidic group contained in the reducing organic substance (basic group/acidic group) is from 0.5 to 1.2.

### Sixth Embodiment

[32]A liquid composition for assisting in bonding of pillars for semiconductor connection to each other, the liquid composition containing: a reducing organic substance; a basic compound; and a coordinating organic compound excluding a compound included in the basic compound, wherein the coordinating organic compound has a boiling point higher than that of the reducing organic substance.

[33] The liquid composition according to [32], wherein the coordinating organic compound is a compound having a carboxyl group.

[34] The liquid composition according to [32] or [33], wherein the reducing organic substance is at least one organic substance selected from formic acid and oxalic acid.

[35] The liquid composition according to any one of [32] to [34], further containing a reducing organic substance other than formic acid.

[36] The copper paste according to any one of [32] to [35], wherein the basic compound is a nitrogen-containing compound represented by the Formula (1) below:

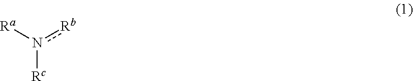

wherein R^{a} to R^{c} are the same or different and each represent a hydrogen atom or a hydrocarbon group optionally having a substituent; the substituents are the same or different and are each at least one group selected from an amino group, an N-substituted amino group, an N,N-substituted amino group, an imino group, an N-substituted imino group, and a hydroxyl group, provided that R^{a} to R^{c} are not hydrogen atoms at the same time; a double line including a broken line represents a single bond or a double bond, and in the case of a double bond, R^{c} is not present; and any two of R^{a} to R^{c} may bond to each other and form a ring together with an adjacent nitrogen atom.

[37] The liquid composition according to any one of [32] to [36], wherein the basic compound has an ethylenediamine structure or an ethanolamine structure in its molecular structure, and an amino group in the ethylenediamine structure or the ethanolamine structure is a tertiary amino group.

[38] The liquid composition according to any one of [32] to [37], wherein a ratio of a total number of moles of basic groups contained in the basic compound to a total number of moles of acidic groups contained in the reducing organic substance (basic group/acidic group) is from 0.4 to 2.5.

[39] The liquid composition according to any one of [32] to [38], further containing a solvent.

### Seventh Embodiment

[40]A method for producing a semiconductor device, the method including applying a liquid composition, particularly, the liquid composition described in any one of [32] to [39], to a bonding portion before the pillars for semiconductor connection are bonded to each other.

[41] Use of a liquid composition for assisting in bonding of pillars for semiconductor connection to each other, the liquid composition containing: a reducing organic substance; a basic compound; and a coordinating organic compound excluding a compound included in the basic compound, wherein the coordinating organic compound has a boiling point higher than that of the reducing organic substance.

### Eighth Embodiment

[42]A method for producing a semiconductor device, the method including:
a first step of applying a photosensitive resin composition on a base material or a semiconductor chip;
a second step of patterning the photosensitive resin composition by photolithography with a maximum interval width being 80 μm or less;
a third step of filling an opening formed by the patterning with a copper paste and drying the copper paste to form a copper pillar;
a fourth step of planarizing a surface having the copper pillar and the patterning without peeling off the photosensitive resin composition; preparing a set of structures obtained through the first step to the fourth step;
a fifth step of applying a liquid composition to the planarized surface of at least one of the set of structures;
a sixth step of stacking the set of structures with the copper pillars being in contact with each other; and
a seventh step of heating the set of structures at 200 °C or lower in an inert atmosphere.

[43] The method for producing a semiconductor device according to [42], wherein the photosensitive resin composition contains: a polymer (A) containing monomer units (A1) and (A2) below:
a monomer unit (A1): a monomer having an alkali-soluble group,
a monomer unit (A2): an aromatic (meth)acrylate having a phenolic hydroxyl group;
a photopolymerization initiator (B); and
a solvent (C).

[44] The method for producing a semiconductor device according to [42] or [43], wherein the copper paste is the copper paste described in any one of [19] to [27].

[45] The method for producing a semiconductor device according to [42], wherein the liquid composition is the liquid composition described in any one of [32] to [39].

### Ninth Embodiment

[46]A method for producing a semiconductor device, the method including:
a first step of applying a thermosetting resin onto a base material or a semiconductor chip on which metal pillars are formed at a pitch with a maximum width of an interval of 80 μm or less;
a second step of planarizing a surface having the metal pillars and the thermosetting resin; preparing a set of structures obtained through the first step and the second step;
a third step of applying a liquid composition to the planarized surface of the metal pillars of at least one of the set of structures;
a fourth step of stacking the set of structures with the metal pillars being in contact with each other; and
a fifth step of heating the set of structures at 200 °C or lower in an inert atmosphere.

[47] The method for producing a semiconductor device according to [46], wherein the liquid composition is the liquid composition described in any one of [32] to [39].

### Tenth Embodiment

[48]A semiconductor device including a semiconductor bonded by a copper pillar and a resin, wherein
the copper pillar is present in an opening of the resin, and
an interval between the openings is 80 μm or less.

According to the first embodiment, it is possible to provide a method for producing a semiconductor device, which can include a reduced number of steps of producing a semiconductor device as compared with the related art.

According to the second or third embodiment, a method for producing a semiconductor device, a polymer (A), and a photosensitive resin composition containing the polymer (A), which allow for patterning at a narrower pitch, can be provided.

According to the fourth or fifth embodiment, the number of steps for forming a copper pillar can be reduced as compared with the related art. In addition, it is possible to provide a copper paste for producing a pillar for semiconductor connection and a method for producing a semiconductor device, which can lower a bonding temperature. In addition, according to the fourth embodiment, it is possible to provide a copper paste having excellent fillability even when a resist opening formed on a semiconductor chip is narrow.

According to the sixth or seventh embodiment, it is possible to provide a liquid composition and a method for producing a semiconductor device, which can further lower the bonding temperature as compared with the related art.

According to the eighth, ninth, and tenth embodiments, it is possible to provide a method for producing a semiconductor device, which can include a reduced number of production steps as compared with the related art and further lower the bonding temperature between structures having metal pillars as compared with the related art.

Hereinafter, an embodiment of the present embodiments will be described in detail. The present embodiments are not limited to the following embodiments, and can be carried out by making appropriate changes as long as the effects of the present embodiments are not impaired.

Each of the configurations, combinations thereof, and the like in each of the embodiments is an example, and various additions, omissions, substitutions, and other changes of the configurations can be made as appropriate without departing from the spirit of the present embodiments. The present embodiments are not limited by the embodiments and are limited only by the claims.

Each aspect disclosed in the present specification can be combined with another feature disclosed in the present specification.

Where a particular description given for an embodiment also applies to another embodiment, that description may be omitted in the other embodiment. In the present embodiments, the expression “from X to Y” with regard to a numerical range means “X or more and Y or less”.

In addition, in a case where a plurality of upper limit values and lower limit values are described for a specific parameter, any upper limit value and any lower limit value among these upper limit values and lower limit values can be combined to obtain a suitable numerical range. In addition, a lower limit value and/or an upper limit value of a numerical range described in the present disclosure is a numerical value that is included within the numerical range and may be replaced with a numerical value presented in the examples.

### DEFINITION

In the present specification, the following terms in parentheses are defined as follows.

The “structure” means a structure including a patterned resin layer including an opening on a substrate or a semiconductor chip, and a metal pillar may be formed in the opening.

The “patterned resin layer” means a resin layer subjected to a patterning treatment. The patterned resin layer usually includes a plurality of openings.

The “bonding” is a term that encompasses adhesion and bonding. For example, the “bonding” may include connecting surfaces of two or more structures each including a patterned resin layer including an opening on a substrate or a semiconductor chip, the surfaces including the patterned resin layer, and adhering the surfaces by applying heat or pressure. In addition, in a case where a metal pillar is formed in the opening, the metal pillars in the openings of the two or more structures may be bonded to each other through metal diffusion by applying heat or pressure.

The “pitch (interval) of the openings” means an interval between center points of adjacent openings formed in the patterned resin layer. Here, an arithmetic mean value of measurements at 10 points is used.

The “opening width of the opening” means the longest width in each opening formed in the patterned resin layer. In a case where the opening has a (substantially) circular shape, it is also referred to as an opening diameter. The opening diameter means a diameter of the opening. Here, an arithmetic mean value of measurement values of 10 openings is used.

The “metal pillar” means a columnar (pillar) electrode formed on a substrate or a semiconductor chip, the cross section of which may not be point-symmetric or line-symmetric.

The “planarization” means eliminating irregularities on a surface where the metal pillar and a pattern of the patterned resin layer exist to flatten the surface.

The “permanent resist” means a resin formed on a substrate or a semiconductor chip and remaining without being removed until a semiconductor device as a finished product is obtained.

The “(meth)acrylate” means acrylate and/or methacrylate.

### First Embodiment: Method for Producing Semiconductor Device

The first embodiment of the present disclosure relates to a method for producing a semiconductor device, the method including:
preparing a structure, including
forming a resin layer on a substrate or a semiconductor chip using a resin composition, and
patterning the resin layer to form a patterned resin layer including an opening; and
bonding two or more of the structures using the patterned resin layer.

According to the first embodiment, it is possible to reduce the number of steps of producing a semiconductor device as compared with the related art.

### Method for Producing Semiconductor Device

A method for producing a semiconductor device according to the present embodiment includes:
preparing a structure, including
forming a resin layer on a substrate or a semiconductor chip using a resin composition, and
patterning the resin layer to form a patterned resin layer including an opening; and
bonding two or more of the structures using the patterned resin layer.

In an embodiment, the substrate is preferably selected from the group consisting of a ceramic substrate, a green sheet, an organic substrate, a glass substrate, and a circuit forming substrate, for example.

In an embodiment, the organic substrate is preferably composed of, for example, glass epoxy, an epoxy resin, a phenol resin, a cycloolefin polymer (COP), a polyimide, a liquid crystal polymer (LCP), a polystyrene, a modified polyphenylene ether, or a fluororesin.

In an embodiment, the semiconductor chip is preferably selected from the group consisting of a silicon chip, a compound semiconductor chip, and a semiconductor package chip, for example.

Examples of the resin composition include a resin composition for a resist containing a photocurable resin and a resin composition containing a thermosetting resin, and the resin composition may contain one or more selected from these.

Examples of the photocurable resin include photocurable acrylic resins, photocurable urethane resins, and photocurable epoxy resins. One type of these may be used alone, or two or more types thereof may be used in combination.

Examples of the thermosetting resin include an epoxy resin, an acrylic resin, a melamine resin, a maleimide resin, a polyurethane resin, a diallyl phthalate resin, and a silicone resin. One type of these may be used alone, or two or more types thereof may be used in combination.

In an embodiment, the resin composition preferably contains a polymer (A) described in the second embodiment described later, from the viewpoint of achieving a lower bonding temperature. When the polymer (A) is contained, a lower bonding temperature of the structure can be achieved (for example, 200 °C or lower). In another embodiment, the resin composition may contain a thermosetting resin described in the ninth embodiment described later.

As a method for forming a patterning including an opening on a substrate or a semiconductor chip using the resin composition, it is preferable to form an etching mask by patterning using photolithography. More specifically, in forming an etching mask, the resin composition is applied onto a semiconductor chip and dried to obtain a coating film, and the coating film is exposed to light through a predetermined mask (and further subjected to post-exposure baking as necessary) to form a latent image pattern, followed by development, whereby an etching mask having a fine pattern with high accuracy can be formed.

In an embodiment, when a patterning having two or more openings is formed on a substrate or a semiconductor chip, a pitch (interval) between adjacent openings is preferably 80 μm or less, more preferably 40 μm or less, even more preferably 20 μm or less, and particularly preferably 10 μm or less.

In an embodiment, when a patterning having two or more openings is formed on a substrate or a semiconductor chip, a lower limit value of the pitch (interval) between adjacent openings is preferably 0.1 μm or more, more preferably 1 μm or more, even more preferably 5 μm or more, and particularly preferably 10 μm.

In an embodiment, when a patterning having two or more openings is formed on a substrate or a semiconductor chip, the pitch (interval) between adjacent openings is preferably one pitch (interval) selected from the group consisting of from 0.1 μm to 80 μm, from 1 μm to 80 μm, from 5 μm to 80 μm, from 10 μm to 80 μm, from 0.1 μm to 40 μm, from 1 μm to 40 μm, from 5 μm to 40 μm, from 10 μm to 40 μm, from 0.1 μm to 20 μm, from 1 μm to 20 μm, from 5 μm to 20 μm, from 10 μm to 20 μm, from 0.1 μm to 10 μm, from 1 μm to 10 μm, and from 5 μm to 10 μm.

In an embodiment, an opening width of the opening is preferably less than 40 μm, more preferably 20 μm, and even more preferably 10 μm. The shape of the opening in plan view is not limited, and examples thereof include a circular shape, an elliptical shape, a rectangular shape, a square shape, an oblong shape, and an indefinite shape.

The photosensitive resin composition can be applied using a typically used application means such as a spin coater, a dip coater, and a roller coater. A thickness of the coating film is, for example, from 0.1 to 30 μm and preferably from 0.3 to 15 μm.

Light rays of various wavelengths (e.g., ultraviolet rays and X-rays) can be used for the exposure. An exposure energy is, for example, from 1 to 1000 mJ/cm².

The photopolymerization initiator (B) and the polymer (A) react with each other by exposure to produce an alkali-soluble group (for example, a hydroxyl group or a carboxy group). Therefore, when the exposed coating film is developed with an alkali developer, an exposed portion of the coating film is dissolved in the alkali developer, and an unexposed portion remains without being dissolved, whereby an etching mask having a predetermined pattern can be formed.

Thereafter, the semiconductor chip is etched using the etching mask obtained in the above step, and the etching mask is removed after the etching, whereby a semiconductor chip having a wiring pattern formed thereon can be obtained.

In an embodiment, removal of the etching mask may not be included. That is, the etching mask formed of the resin composition may be used as a permanent resist. By not removing the etching mask, the number of steps of producing a semiconductor device can be reduced. Furthermore, adjustment of the film thickness of the permanent resist is preferable, since patterning with a high aspect ratio is also possible.

In an embodiment, preparation of a structure preferably includes producing a metal pillar in the opening.

In an embodiment, the production of a metal pillar preferably includes filling the opening with a copper paste, the copper paste preferably contains copper particles and a dispersion medium containing a basic compound and a reducing organic substance, and a molar ratio of a basic group contained in the basic compound to an acidic group contained in the reducing organic substance (basic group/acidic group) is preferably from 0.5 to 1.2.

When the production of a metal pillar includes filling the opening with a copper paste, the pillar can be formed more simply. When the copper paste contains copper particles and a dispersion medium containing a basic compound and a reducing organic substance and satisfies a predetermined molar ratio (basic group/acidic group), a lower temperature at the time of bonding structures can be achieved (for example, 200 °C or lower).

In an embodiment, the method preferably further includes planarizing a surface where the metal pillar and a pattern of the patterned resin layer exist, prior to the bonding. By the planarization, bondability between bonding surfaces is further improved, distortion inside the semiconductor device is reduced, and the possibility of occurrence of a short circuit can be reduced.

In an embodiment, the planarization may be performed by a physical polishing method, such as a surface planar, or a chemical polishing method using a chemical, such as etching, but is preferably performed by chemical mechanical polishing (CMP).

In an embodiment, the bonding preferably includes bonding two or more of the structures at a temperature of 200 °C or higher and 250 °C or lower, more preferably at a temperature of lower than 200 °C, with the metal pillars of the respective structures overlapping each other (such that the patterned resin layers are bonded to each other, and the metal pillars are bonded to each other).

In an embodiment, the method preferably includes applying a liquid composition to a bonding portion of the metal pillar before the bonding. By application of a liquid composition to a bonding portion of the metal pillar, a lower bonding temperature can be achieved (for example, 200 °C or lower).

In an embodiment, the liquid composition contains a reducing organic substance, a basic compound, and a coordinating organic compound excluding a compound included in the basic compound, and the coordinating organic compound has a boiling point higher than that of the reducing organic substance. Use of the liquid composition can further lower the bonding temperature.

### Second Embodiment: Polymer (A)

The second embodiment relates to a polymer (A) for producing the resin composition in a method for producing a semiconductor device, particularly, the method for producing a semiconductor device described above, the polymer (A) including monomer units (A1) and (A2) below:
a monomer unit (A1): a monomer having an alkali-soluble group,
a monomer unit (A2): an aromatic (meth)acrylate having a phenolic hydroxyl group.

The polymer (A) according to the second embodiment can be patterned at a narrower pitch.

### Monomer Unit (A1)

The polymer (A) according to the first embodiment includes a monomer unit (A1). The monomer unit (A1) is a monomer unit derived from a monomer having an alkali-soluble group. The monomer unit (A1) functions to impart alkali solubility to the polymer (A). The polymer (A) according to the first embodiment includes the monomer unit (A1), and thus can be dissolved in an aqueous alkali solution (developer) during development. In addition, the monomer unit (A1) is crosslinked using a crosslinking agent or reacted with, for example, the monomer unit (A2) to a monomer unit (A4) in molecules of the polymer (A) during exposure, thereby curing the polymer (A), and can impart hardness necessary for a resist to the resulting film, and also exhibit a function of changing the polymer (A) to be alkali-insoluble. In an embodiment, the polymer (A) may be used particularly for a negative photoresist.

The monomer unit (A1) can be introduced into the polymer (A) by copolymerization of a polymerizable unsaturated compound (a1) having an alkali-soluble group with an additional monomer. The alkali-soluble group may be any group that is commonly used in the field of resists, and examples thereof include a carboxy group and a phenolic hydroxyl group. Typical examples of the polymerizable unsaturated compound (a1) having an alkali-soluble group include unsaturated carboxylic acids or acid anhydrides thereof, and hydroxystyrene or derivatives thereof, but are not limited thereto. Among these, unsaturated carboxylic acids or acid anhydrides thereof are particularly preferable.

Examples of the unsaturated carboxylic acids or acid anhydrides thereof include α,β-unsaturated carboxylic acids such as acrylic acid, methacrylic acid, itaconic acid, crotonic acid, maleic acid, and fumaric acid, and acid anhydrides thereof (maleic anhydride, itaconic anhydride, and the like). Among these, acrylic acid and/or methacrylic acid is particularly preferable. One type of the polymerizable unsaturated compound (a1) having an alkali-soluble group may be used alone, or two or more types thereof may be used in combination.

In an embodiment, a proportion of the monomer unit (A1) to a total amount (100 mol %) of all the monomer units constituting the polymer (A) is preferably from 5 to 50 mol %, more preferably from 5 to 40 mol %, and even more preferably from 5 to 30 mol %. When the proportion of the monomer unit (A1) is within the above range, developability is likely to be good, and etching resistance after development is also likely to be good.

### Monomer Unit (A2)

The polymer (A) according to the first embodiment includes a monomer unit (A2). The monomer unit (A2) is a monomer unit derived from an aromatic (meth)acrylate having a phenolic hydroxyl group. The polymer (A) according to the first embodiment includes the monomer unit (A2), and thus a patterning with a narrower pitch can be formed.

Examples of the aromatic (meth)acrylate having a phenolic hydroxyl group include hydroxyphenyl (meth)acrylate, and p-hydroxyphenyl methacrylate and/or p-hydroxyphenyl acrylate is preferable.

In an embodiment, a proportion of the monomer unit (A2) to the total amount (100 mol %) of all the monomer units constituting the polymer (A) is preferably from 5 to 50 mol %, more preferably from 5 to 40 mol %, and even more preferably from 5 to 30 mol %. When the proportion of the monomer unit (A2) is within the above range, a patterning with a narrow pitch is easily formed stably.

### Monomer Unit (A3)

The polymer (A) according to the first embodiment preferably further includes a monomer unit (A3). The monomer unit (A3) is a monomer unit derived from an N-substituted maleimide compound. The polymer (A) according to the second embodiment includes the monomer unit (A3), and thus good heat resistance can be achieved.

Examples of the N-substituted maleimide compound include a compound represented by Formula (1) below.

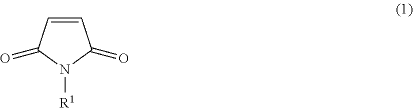

(In Formula (1), R¹ represents an organic group.)

Examples of the organic group include a hydrocarbon group and a heterocyclic group.

Examples of the hydrocarbon group include alkyl groups (for example, C1-6 alkyl groups) such as a methyl group, an ethyl group, a propyl group, an isopropyl group, a butyl group, and a hexyl group; cycloalkyl groups such as a cyclopentyl group, a cyclohexyl group, a cyclooctyl group, an adamantyl group, and a norbornyl group; aryl groups such as a phenyl group; aralkyl groups such as a benzyl group; and groups in which two or more of these are bonded. Examples of the heterocyclic group include 5- to 10-membered heterocycloalkyl groups and heteroaryl groups containing at least one heteroatom selected from the group consisting of a nitrogen atom, an oxygen atom, and a sulfur atom.

As the N-substituted maleimide compound, one or more compounds represented by Formula (1) above can be adopted, and examples thereof include N-alkylmaleimides such as N-methylmaleimide, N-ethylmaleimide, and N-propylmaleimide; N-cycloalkylmaleimides such as N-cyclopentylmaleimide, N-cyclohexylmaleimide, N-cyclooctylmaleimide, N-adamantylmaleimide, and N-norbornylmaleimide; N-arylmaleimides such as N-phenylmaleimide; and N-aralkylmaleimides such as N-benzylmaleimide. One type of the N-substituted maleimide compound may be used alone, or two or more types thereof may be used in combination.

Among these, N-methylmaleimide, N-phenylmaleimide, and N-cyclohexylmaleimide are preferably contained, and N-cyclomaleimide is more preferably contained.

In an embodiment, a proportion of the monomer unit (A3) to the total amount (100 mol %) of all the monomer units constituting the polymer (A) is preferably from 5 to 60 mol %, more preferably from 10 to 50 mol %, and even more preferably from 15 to 45 mol %. When the proportion of the monomer unit (A3) is within the above range, good heat resistance is easily achieved.

### Monomer Unit (A4)

The polymer (A) according to the first embodiment preferably includes a monomer unit (A4). The monomer unit (A4) is a monomer unit derived from an alkyl (meth)acrylate having an alkyl group with 2 or more carbon atoms. The polymer (A) according to the first embodiment includes the monomer unit (A4), and thus good flexibility can be achieved.

Examples of the alkyl (meth)acrylate having an alkyl group with 2 or more carbon atoms include alkyl (meth)acrylates having an alkyl group with 2 or more and 12 or less carbon atoms, such as ethyl (meth)acrylate, propyl (meth)acrylate, butyl (meth)acrylate, t-butyl (meth)acrylate, pentyl (meth)acrylate, and hexyl (meth)acrylate. Among these, ethyl and ethylhexyl butyl (meth)acrylate are preferably contained, and butyl acrylate is particularly preferably contained.

In an embodiment, a proportion of the monomer unit (A4) to the total amount (100 mol %) of all the monomer units constituting the polymer (A) is preferably from 5 to 60 mol %, more preferably from 10 to 50 mol %, and even more preferably from 15 to 45 mol %. When the proportion of the monomer unit (A4) is within the above range, good flexibility is easily achieved.

### Additional Monomer Unit

In an embodiment, the polymer (A) can include an additional monomer unit besides the monomer units (A1) to (A4) described above.

Examples of the additional monomer unit include a unit derived from a monomer having a phenolic hydroxyl group and a polymerizable unsaturated group other than the monomer unit (A2), a unit derived from a (meth)acrylate compound other than the monomer unit (A4), a unit derived from a monomer having a hydroxyalkyl group and a polymerizable unsaturated group, an acrylamide compound-derived unit, an acrylonitrile unit, a styrene compound-derived unit, and a vinyl compound-derived unit. The polymer (A) can include one or more of these additional monomer units. Specific examples of monomers that can constitute the additional monomer units are described below, but the monomers are not limited thereto.

Examples of the monomer having a phenolic hydroxyl group and a polymerizable unsaturated group other than the monomer unit (A2) include p-hydroxystyrene, α-methyl-p-hydroxystyrene, N-hydroxyphenylmaleimide, N-hydroxyphenylacrylamide, and N-hydroxyphenylmethacrylamide. One type of these may be used alone, or two or more types thereof may be used in combination.

Examples of the (meth)acrylate compound other than the monomer unit (A4) include methyl (meth)acrylate, benzyl (meth)acrylate, naphthyl (meth)acrylate, anthryl (meth)acrylate, anthrylmethyl (meth)acrylate, phenyl (meth)acrylate, glycidyl (meth)acrylate, phenoxyethyl (meth)acrylate, 2,2,2-trifluoroethyl (meth)acrylate, cyclohexyl (meth)acrylate, isobornyl (meth)acrylate, 2-methoxyethyl (meth)acrylate, methoxytriethylene glycol (meth)acrylate, 2-ethoxyethyl (meth)acrylate, 2-aminoethyl (meth)acrylate, tetrahydrofurfuryl (meth)acrylate, 3-methoxybutyl (meth)acrylate, 2-methyl-2-adamantyl (meth)acrylate, 2-propyl-2-adamantyl (meth)acrylate, 8-ethyl-8-tricyclodecyl (meth)acrylate, 8-methyl-8-tricyclodecyl (meth)acrylate, diethylene glycol mono(meth)acrylate, caprolactone-2-(acryloyloxy)ethyl ester, and polyethylene glycol ethyl ether (meth)acrylate. One type of these may be used alone, or two or more types thereof may be used in combination.

Examples of the monomer having a hydroxyalkyl group and a polymerizable unsaturated group include 2-hydroxyethyl (meth)acrylate, 2-hydroxypropyl (meth)acrylate, 4-hydroxybutyl (meth)acrylate, 2,3-dihydroxypropyl (meth)acrylate, glycerol mono(meth)acrylate, and 5-acryloyloxy-6-hydroxynorbornene-2-carboxylic-6-lactone. One type of these may be used alone, or two or more types thereof may be used in combination.

Examples of the acrylamide compound include N-methylacrylamide, N-methylmethacrylamide, N,N-dimethylacrylamide, N,N-dimethylmethacrylamide, N-methoxymethylacrylamide, N-methoxymethylmethacrylamide, N-butoxymethylacrylamide, and N-butoxymethylmethacrylamide. One type of these may be used alone, or two or more types thereof may be used in combination.

Examples of the styrene compound include styrene having no hydroxy group, and examples thereof include styrene, u-methylstyrene, chlorostyrene, and bromostyrene. One type of these may be used alone, or two or more types thereof may be used in combination.

Examples of the vinyl compound include methyl vinyl ether, benzyl vinyl ether, cyclohexyl vinyl ether, vinyl naphthalene, vinyl anthracene, vinyl carbazole, allyl glycidyl ether, 3-ethenyl-7-oxabicyclo[4.1.0]heptane, 1,2-epoxy-5-hexene, and 1,7-octadiene monoepoxide. One type of these may be used alone, or two or more types thereof may be used in combination.

In an embodiment, when the polymer (A) includes one or more additional monomer units, a proportion thereof is preferably 40 mol % or less relative to the total amount (100 mol %) of all the monomer units constituting the polymer (A).

In an embodiment, a weight average molecular weight (Mw) of the polymer (A) is not particularly limited, and is, for example, preferably from 2000 to 300000, more preferably from 3000 to 100000, and even more preferably from 5000 to 50000. A molecular weight distribution (ratio of weight average molecular weight to number average molecular weight: Mw/Mn) of the polymer (A) is not particularly limited, and is, for example, preferably 5.0 or less, more preferably from 1.2 to 4.5, and even more preferably from 1.5 to 4.0. In the present disclosure, the weight average molecular weight (Mw) and the number average molecular weight (Mn) can be measured by GPC using polystyrene as a standard material.

### Method for Producing Polymer (A)

The polymer (A) according to the second embodiment can be produced by blending monomers constituting the monomer units (A1) and (A2) described above and, if necessary, one or more monomers constituting additional monomer units, and copolymerizing these monomers.

The polymer (A) according to the second embodiment may be copolymerized in the presence of a polymerization initiator. As the polymerization initiator, typical or known radical polymerization initiators can be used, and examples thereof include azo compounds such as 2,2′-azobisisobutyronitrile, 2,2′-azobis(2,4-dimethylvaleronitrile), 2,2′-azobis(4-methoxy-2,4-dimethylvaleronitrile), dimethyl-2,2′-azobis(2-methylpropionate), diethyl-2,2′-azobis(2-methylpropionate), and dibutyl-2,2′-azobis(2-methylpropionate); organic peroxides such as benzoyl peroxide, lauroyl peroxide, t-butylperoxypivalate, and 1,1-bis(t-butylperoxy)cyclohexane; and hydrogen peroxide.

When a peroxide is used as the radical polymerization initiator, the peroxide may be combined with a reducing agent and used as a redox initiator. Among these, azo compounds are preferable, and 2,2′-azobisisobutyronitrile, 2,2′-azobis(2,4-dimethylvaleronitrile), and dimethyl-2,2′-azobis(2-methylpropionate) are more preferable.

The amount of the polymerization initiator to be used can be appropriately selected as long as smooth copolymerization is not impaired, and is not particularly limited. It is, for example, preferably from 1 to 20 parts by weight, and more preferably from 3 to 15 parts by weight, relative to a total amount (100 parts by weight) of the monomers.

The polymer (A) according to the second embodiment can be produced by a known method used for producing an acrylic polymer or a styrene-based polymer, such as solution polymerization, bulk polymerization, suspension polymerization, bulk-suspension polymerization, or emulsion polymerization. Each of the monomers and the polymerization initiator as described above may be supplied to a reaction system at once, or a part or all thereof may be added dropwise to the reaction system. For example, a method of polymerization by adding dropwise a solution containing the polymerization initiator dissolved in a polymerization solvent to each monomer or a mixed liquid of a monomer and a polymerization solvent kept at a constant temperature, a method of polymerization by dissolving a monomer and a polymerization initiator in a polymerization solvent in advance and adding dropwise the solution to a polymerization solvent kept at a constant temperature (dropwise polymerization), and the like can be adopted.

In an embodiment, the polymer (A) is preferably copolymerized in a polymerization solvent. The polymerization solvent can be appropriately selected according to the composition of the monomer and the like, and examples thereof include ethers (e.g., chain ethers such as diethyl ether, glycol ethers such as ethylene glycol mono- or dialkyl ethers, diethylene glycol mono- or dialkyl ethers, propylene glycol mono- or dialkyl ethers, propylene glycol mono- or diaryl ethers, dipropylene glycol mono- or dialkyl ethers, tripropylene glycol mono- or dialkyl ethers, 1,3-propanediol mono- or dialkyl ethers, 1,3-butanediol mono- or dialkyl ethers, 1,4-butanediol mono- or dialkyl ethers, and glycerol mono-, di- or trialkyl ethers; and cyclic ethers such as tetrahydrofuran and dioxane), esters (e.g., carboxylate esters such as methyl acetate, ethyl acetate, butyl acetate, isoamyl acetate, ethyl lactate, methyl 3-methoxypropionate, ethyl 3-ethoxypropionate, C5-6 cycloalkanediol mono- or diacetate, and C5-6 cycloalkanedimethanol mono- or diacetate; and glycol acetates or glycol ether acetates such as ethylene glycol monoalkyl ether acetate, ethylene glycol mono- or diacetate, diethylene glycol monoalkyl ether acetate, diethylene glycol mono- or diacetate, propylene glycol monoalkyl ether acetate, propylene glycol mono- or diacetate, dipropylene glycol monoalkyl ether acetate, dipropylene glycol mono- or diacetate, 1,3-propanediol monoalkyl ether acetate, 1,3-propanediol mono- or diacetate, 1,3-butanediol monoalkyl ether acetate, 1,3-butanediol mono- or diacetate, 1,4-butanediol monoalkyl ether acetate, 1,4-butanediol mono- or diacetate, glycerol mono-, di- or triacetate, glycerol mono- or di-C1-4 alkyl ether di- or monoacetate, tripropylene glycol monoalkyl ether acetate, and tripropylene glycol mono- or diacetate), ketones (e.g., acetone, methyl ethyl ketone, methyl isobutyl ketone, cyclohexanone, and 3,5,5-trimethyl-2-cyclohexen-1-one), amides (e.g., N,N-dimethylacetamide and N,N-dimethylformamide), sulfoxides (e.g., dimethyl sulfoxide), alcohols (e.g., methanol, ethanol, propanol, C5-6 cycloalkanediol, and C5-6 cycloalkanedimethanol), hydrocarbons (e.g., aromatic hydrocarbons such as benzene, toluene, and xylene, aliphatic hydrocarbons such as hexane, and alicyclic hydrocarbons such as cyclohexane), and mixed solvents thereof. Any of these polymerization solvents can be adopted, but in an embodiment, the polymerization solvent is preferably an ester, and more preferably propylene glycol monoalkyl ether acetate.

A polymerization temperature can be appropriately selected depending on the type and composition of the monomer, and is not particularly limited, but is preferably from 30 to 150 °C, for example.

A reaction solution containing the polymer (A) and obtained by the above method can be purified by precipitation or reprecipitation, if necessary. A solvent used for precipitation or reprecipitation may be an organic solvent or water, or a mixed solvent thereof.

Examples of the organic solvent include hydrocarbons (aliphatic hydrocarbons such as pentane, hexane, heptane, and octane; alicyclic hydrocarbons such as cyclohexane and methylcyclohexane; and aromatic hydrocarbons such as benzene, toluene, and xylene), halogenated hydrocarbons (e.g., halogenated aliphatic hydrocarbons such as methylene chloride, chloroform, and carbon tetrachloride; and halogenated aromatic hydrocarbons such as chlorobenzene and dichlorobenzene), nitro compounds (e.g., nitromethane and nitroethane), nitriles (e.g., acetonitrile and benzonitrile), ethers (chain ethers such as diethyl ether, diisopropyl ether, and dimethoxyethane; and cyclic ethers such as tetrahydrofuran and dioxane), ketones (e.g., acetone, methyl ethyl ketone, and diisobutyl ketone), esters (e.g., ethyl acetate and butyl acetate), carbonates (e.g., dimethyl carbonate, diethyl carbonate, ethylene carbonate, and propylene carbonate), alcohols (e.g., methanol, ethanol, propanol, isopropyl alcohol, and butanol), carboxylic acids (e.g., acetic acid), and mixed solvents containing these solvents.

### Third Embodiment: Photosensitive Resin Composition

The third embodiment of the present embodiments relates to a photosensitive resin composition containing the polymer (A) according to the second embodiment, a photopolymerization initiator (B), and a solvent (C). The photosensitive resin composition according to the second embodiment is a resin composition containing the polymer (A) according to the second embodiment as an essential component. According to the third embodiment, patterning can be performed at a narrower pitch. Furthermore, since the photosensitive resin composition according to the third embodiment can also be used as a permanent resist, bonding of metal pillars with a narrower pitch to each other can be performed in fewer steps than in the related art.

### Photopolymerization Initiator (B)

The photosensitive resin composition according to the third embodiment contains a photopolymerization initiator (B) as a curing catalyst. Examples of the photopolymerization initiator (B) include an alkylphenone-based photoradical generator, an acylphosphine oxide-based photoradical generator, an oxime ester-based photoradical generator, and an a-hydroxyketone-based photoradical generator.

Examples of the alkylphenone-based photoradical generator include oligomers of 2-hydroxy-2-methyl-1-phenylpropan-1-one, 2-benzyl-2-dimethylamino-1-(4-morpholinophenyl)-1-butanone, 2-(dimethylamino)-2-[(4-methylphenyl)methyl]-[4-(4-morpholinyl) phenyl]-1-butanone, 2-methyl-1-[4-(methylthio)phenyl]-2-morpholinopropan-1-one, benzophenone, methylbenzophenone, o-benzoylbenzoic acid, benzoylethyl ether, 2,2-diethoxyacetophenone, 2,4-diethylthioxanthone, diphenyl (2,4,6-trimethylbenzoyl)phosphine oxide, ethyl-(2,4,6-trimethylbenzoyl) phenylphosphinate, 4,4′-bis(diethylamino)benzophenone, 1-hydroxycyclohexylphenyl ketone, 2,2-dimethoxy-1,2-diphenylethan-1-one, 1-[4-(2-hydroxyethoxy)phenyl]-2-hydroxy-2-methyl-1-propan-1-one, and 2-hydroxy-1-(4-isopropenylphenyl)-2-methylpropan-1-one. One type of these may be used alone, or two or more types thereof may be used in combination.

Examples of the acylphosphine oxide-based photoradical generator include diphenyl (2,4,6-trimethylbenzoyl)phosphine oxide and ethyl-(2,4,6-trimethylbenzoyl) phenylphosphinate. One type of these may be used alone, or two or more types thereof may be used in combination.

Examples of the oxime ester-based photoradical generator include 1-[4-(phenylthio)phenyl]-1,2-octandione 2-(O-benzoyloxime), 1-[6-(2-methylbenzoyl)-9-ethyl-9H-carbazol-3-yl]ethanone O-acetyloxime, and 6-[1-(acetyloxyimino)ethyl]-9-ethyl-9H-carbazol-3-yl(2-methylphenyl)ketone. One type of these may be used alone, or two or more types thereof may be used in combination.

Examples of the a-hydroxyketone-based photoradical generator include benzoin, benzoin methyl ether, benzoin butyl ether, 1-hydroxycyclohexylphenyl ketone, 1-phenyl-2-hydroxy-2-methylpropan-1-one, 1-(4-i-propylphenyl)-2-hydroxy-2-methylpropan-1-one, 4-(2-hydroxyethoxy)phenyl-(2-hydroxy-2-propyl)ketone, and 1-hydroxycyclohexylphenyl ketone. One type of these may be used alone, or two or more types thereof may be used in combination.

In an embodiment, a proportion of the photopolymerization initiator (B) is preferably from 1.0 to 10.0 parts by mass, more preferably from 2.0 to 8.0 parts by mass, and even more preferably from 2.5 to 6.0 parts by mass, relative to 100 parts by mass of the polymer component containing the polymer (A). When the proportion of the photopolymerization initiator (B) is within the above range, curing failure is less likely to occur.

### Solvent (C)

The photosensitive resin composition according to the third embodiment contains a solvent (C). As the solvent (C), there can be used ethers (e.g., chain ethers such as diethyl ether, glycol ethers such as ethylene glycol mono- or dialkyl ethers, diethylene glycol mono- or dialkyl ethers, propylene glycol mono- or dialkyl ethers, propylene glycol mono- or diaryl ethers, dipropylene glycol mono- or dialkyl ethers, tripropylene glycol mono- or dialkyl ethers, 1,3-propanediol mono- or dialkyl ethers, 1,3-butanediol mono- or dialkyl ethers, 1,4-butanediol mono- or dialkyl ethers, and glycerol mono-, di- or trialkyl ethers; and cyclic ethers such as tetrahydrofuran and dioxane), esters (e.g., carboxylate esters such as methyl acetate, ethyl acetate, butyl acetate, isoamyl acetate, ethyl lactate, methyl 3-methoxypropionate, ethyl 3-ethoxypropionate, C5-6 cycloalkanediol mono- or diacetate, and C5-6 cycloalkanedimethanol mono- or diacetate; and glycol acetates or glycol ether acetates such as ethylene glycol monoalkyl ether acetate, ethylene glycol mono- or diacetate, diethylene glycol monoalkyl ether acetate, diethylene glycol mono- or diacetate, propylene glycol monoalkyl ether acetate, propylene glycol mono- or diacetate, dipropylene glycol monoalkyl ether acetate, dipropylene glycol mono- or diacetate, 1,3-propanediol monoalkyl ether acetate, 1,3-propanediol mono- or diacetate, 1,3-butanediol monoalkyl ether acetate, 1,3-butanediol mono- or diacetate, 1,4-butanediol monoalkyl ether acetate, 1,4-butanediol mono- or diacetate, glycerol mono-, di- or triacetate, glycerol mono- or di-C1-4 alkyl ether di- or monoacetate, tripropylene glycol monoalkyl ether acetate, and tripropylene glycol mono- or diacetate), ketones (e.g., acetone, methyl ethyl ketone, methyl isobutyl ketone, cyclohexanone, and 3,5,5-trimethyl-2-cyclohexen-1-one), or mixed solvents thereof.

### Additional Polymer

The photosensitive resin composition according to the third embodiment may contain a polymer component (additional polymer) besides the polymer (A). Examples of the additional polymer include a polyfunctional vinyl compound, a polyfunctional thiol compound, and a polyfunctional epoxy compound.

The polyfunctional vinyl compound is not particularly limited as long as it is a compound having two or more vinyl groups, and examples thereof include di(meth)acrylates of alkylene glycols such as ethylene glycol and propylene glycol; di(meth)acrylates of polyalkylene glycols such as polyethylene glycol and polypropylene glycol; di(meth)acrylates of both-end hydroxylated polymers, such as both-end hydroxypolybutadiene, both-end hydroxypolyisoprene, and both-end hydroxypolycaprolactone; poly(meth)acrylates of trihydric or higher polyhydric alcohols, such as glycerin, 1,2,4-butanetriol, trimethylolalkane, tetramethylolalkane, pentaerythritol, and dipentaerythritol; poly(meth)acrylates of polyalkylene glycol adducts of trihydric or higher polyhydric alcohols; poly(meth)acrylates of cyclic polyols such as 1,4-cyclohexanediol and 1,4-benzenediol; and oligo(meth)acrylates such as polyester (meth)acrylate, epoxy (meth)acrylate, urethane (meth)acrylate, and silicone resin (meth)acrylate. One type of the polyfunctional vinyl compound may be used alone, or two or more types thereof may be used in combination.

The polyfunctional thiol compound is not particularly limited as long as it is a compound having two or more thiol groups, and examples thereof include hexanedithiol, decanedithiol, 1,4-butanediol bisthiopropionate, 1,4-butanediol bisthioglycolate, ethylene glycol bisthioglycolate, ethylene glycol bisthiopropionate, trimethylolpropane tristhioglycolate, trimethylolpropane tristhiopropionate, trimethylolpropane tris(3-mercaptobutyrate), pentaerythritol tetrakisthioglycolate, pentaerythritol tetrakisthiopropionate, tris(2-hydroxyethyl)isocyanurate trimercaptopropionate, 1,4-dimethylmercaptobenzene, 2,4,6-trimercapto-s-triazine, 2-(N,N-dibutylamino)-4,6-dimercapto-s-triazine, tetraethylene glycol bis-3-mercaptopropionate, trimethylolpropane tris-3-mercaptopropionate, tris(3-mercaptopropynyloxyethyl)isocyanurate, pentaerythritol tetrakis-3-mercaptopropionate, dipentaerythritol tetrakis-3-mercaptopropionate, 1,4-bis(3-mercaptobutyryloxy)butane, 1,3,5-tris(3-mercaptobutyloxyethyl)-1,3,5-triazine-2,4,6(1H,3H,5H)-trione, and pentaerythritol tetrakis(3-mercaptobutyrate). One type of the polyfunctional thiol compound may be used alone, or two or more types thereof may be used in combination.

The polyfunctional epoxy compound is not particularly limited as long as it is a compound having two or more epoxy groups, and examples thereof include glycidyl ether type epoxy compounds [glycidyl ethers (for example, (poly)C2-4 alkylene glycol diglycidyl ethers such as ethylene glycol diglycidyl ether, diethylene glycol diglycidyl ether, and polyethylene glycol diglycidyl ether; diglycidyl ethers of polyhydric phenols such as resorcin and hydroquinone; diglycidyl ethers of alicyclic polyhydric alcohols such as cyclohexanediol, cyclohexanedimethanol, and hydrogenated bisphenols; diglycidyl ethers of bisphenols (e.g., 4,4′-dihydroxybiphenyl, and bis(hydroxyphenyl)alkanes such as bisphenol A) or C2-3 alkylene oxide adduct thereof) produced by reaction of polyhydroxy compounds (e.g., bisphenols, polyhydric phenols, alicyclic polyhydric alcohols, and aliphatic polyhydric alcohols) with epichlorohydrin, novolac type epoxy resins (e.g., phenol novolac type or cresol novolac type epoxy resins), and the like], glycidyl ester type epoxy compounds, alicyclic epoxy compounds (or cyclic aliphatic epoxy resins), heterocyclic epoxy resins (e.g., triglycidyl isocyanurate (TGIC), and hydantoin type epoxy resin), and glycidyl amine type epoxy compounds [reaction products of amines and epichlorohydrin, for example, N-glycidyl aromatic amines {tetraglycidyl diaminodiphenylmethane (TGDDM), triglycidyl aminophenol (e.g., TGPAP and TGMAP), diglycidyl aniline (DGA), diglycidyl toluidine (DGT), tetraglycidyl xylylenediamine (TGMXA, etc.), and the like}, N-glycidyl alicyclic amines (e.g., tetraglycidyl bisaminocyclohexane), and the like]. One type of the polyfunctional epoxy compound may be used alone, or two or more types thereof may be used in combination.

### Additional Component

The photosensitive resin composition according to the third embodiment can contain an additional component in addition to the above-described components. As the additional component, one or more of: a resin such as a novolac resin, a phenol resin, an imide resin, or a carboxy group-containing resin, a radical polymerization initiator, a curing agent, a curing accelerator, and an additive (a filler, an antifoaming agent, a flame retardant, an antioxidant, an ultraviolet absorber, a colorant, a stress-reducing agent, a flexibility-imparting agent, a wax, a resin, a crosslinking agent, a halogen trapping agent, a leveling agent, a wetting improver, or the like) may be contained.

In the photosensitive resin composition according to the third embodiment, a content of the polymer (A) is not particularly limited, and is, for example, preferably from 3 to 50 mass % relative to a total mass of the photosensitive resin composition. In addition, a weight ratio of a total amount (100 mass %) of curable components contained in the photosensitive resin composition to the polymer (A) is also not particularly limited, and is, for example, preferably from 5:1 to 1:10, more preferably from 3:1 to 1:8, even more preferably from 2:1 to 1:5, and particularly preferably from 1:1 to 1:3.

### Application

The photosensitive resin composition according to the third embodiment contains the polymer (A) according to the second embodiment, and can be patterned at a narrower pitch, and therefore can be suitably used as a resin composition for a semiconductor device, particularly, for a resist of a semiconductor device.

### Fourth Embodiment: Copper Paste

The fourth embodiment of the present disclosure relates to a copper paste for producing a copper pillar for semiconductor connection, the copper paste containing:
copper particles; and
a dispersion medium containing a basic compound and a reducing organic substance,
wherein a molar ratio of a basic group contained in the basic compound to an acidic group contained in the reducing organic substance (basic group/acidic group) is from 0.5 to 1.2.

According to the fourth embodiment, the number of steps for forming a copper pillar can be reduced as compared with the related art. In addition, it is possible to provide a copper paste for producing a pillar for semiconductor connection, which can lower the bonding temperature.

In the fourth embodiment, the “copper pillar for semiconductor connection” means a columnar (pillar) copper electrode formed on a substrate or a semiconductor chip, the cross section of which may not be point-symmetric or line-symmetric.

### Copper Particles

In the copper paste for producing a copper pillar for semiconductor connection according to the fourth embodiment, the “copper particles” mean particles containing at least one selected from particles of copper or an oxide of copper (copper oxide (Cu₂O, CuO), or the like) as a main component.

The copper particles may contain a metal and an oxide thereof besides copper and an oxide of copper, but are preferably composed of copper particles alone.

In an embodiment, the shape of the copper particles may be various shapes such as a spherical shape, an ellipsoidal flake shape (flat shape), and a fibrous shape, and may be an indefinite shape, but is preferably a spherical shape or a flake shape from the viewpoint of the coating properties and storage stability of the copper paste. One type of these may be used alone, or two or more types thereof may be used in combination.

In an embodiment, a volume average particle size (median diameter; D50) of the above-described metal particles is preferably from 1 nm to 500 μm, more preferably from 1 nm to 400 μm, even more preferably from 1 nm to 300 μm, particularly preferably from 1 nm to 200 μm, and most preferably from 1 nm to 100 nm.

A volume average particle size of the copper particles can be measured, for example, using a commercially available laser type particle size distribution meter (for example, SALD-7000 available from Shimadzu Corporation).

In an embodiment, when particles of a metal and an oxide thereof other than copper and an oxide of copper (hereinafter, also referred to as additional metal particles) are used in combination, a weight ratio of the copper particles to all the particles (copper particles/all particles) is preferably from 0.35 to 0.9, more preferably from 0.4 to 0.87, and even more preferably from 0.45 to 0.84.

In an embodiment, a content of the copper particles in the copper paste (a total content when two or more types of copper particles and/or copper particles having two or more particle sizes are contained) is preferably from 50 to 85 wt. %, more preferably from 50 to 80 wt. %, even more preferably from 50 to 75 wt. %, particularly preferably from 50 to 70 wt. %, and most preferably from 50 to 60 wt. %.

### Dispersion Medium

The copper paste for producing a copper pillar for semiconductor connection according to the fourth embodiment contains a dispersion medium containing a basic compound and a reducing organic substance, and a molar ratio (basic group/acidic group) of a basic group contained in the basic compound and an acidic group contained in the reducing organic substance is from 0.5 to 1.2.

### Basic Compound

The basic compound in the present disclosure increases the temperature at which formic acid volatilizes in the copper paste, allows a miscible material to be a good dispersion medium, and suppresses corrosion of surfaces of the copper particles by formic acid.

In an embodiment, the basic compound is preferably a nitrogen-containing compound represented by Formula (1) below:

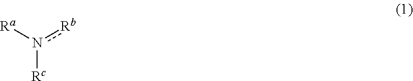

where R^{a} to R^{c} are the same or different and each represent a hydrogen atom or a hydrocarbon group optionally having a substituent; the substituents are the same or different and are each at least one group selected from an amino group, an N-substituted amino group, an N,N-substituted amino group, an imino group, an N-substituted imino group, and a hydroxyl group, provided that R^{a} to R^{c} are not hydrogen atoms at the same time; a double line including a broken line represents a single bond or a double bond, and in the case of a double bond, R^{c} is not present; and any two of R^{a} to R^{c} may bond to each other and form a ring together with an adjacent nitrogen atom.

In one embodiment, examples of the hydrocarbon group related to R^{a} to R^{c} include an aliphatic hydrocarbon group, an alicyclic hydrocarbon group, and an aromatic hydrocarbon group, and, among them, an aliphatic hydrocarbon group and an alicyclic hydrocarbon group are preferable, and an aliphatic hydrocarbon group is more preferable.

In an embodiment, examples of the aliphatic hydrocarbon group include a linear or branched alkyl group, a linear or branched alkenyl group, a linear or branched alkynyl group, and a linear or branched alkylidene group, and, among them, a linear or branched alkyl group is preferable.

In an embodiment, the linear or branched alkyl group is a linear alkyl group having preferably from 1 to 12 carbon atoms, more preferably from 1 to 8 carbon atoms, and even more preferably from 2 to 4 carbon atoms, or a branched alkyl group having preferably from 3 to 12 carbon atoms, more preferably from 3 to 8 carbon atoms, and even more preferably from 3 to 6 carbon atoms. Examples of the linear or branched alkyl group include a methyl group, an ethyl group, a propyl group, a butyl group, a pentyl group, a hexyl group, a decyl group, a dodecyl group, a tetradecyl group, an octadecyl group, an isopropyl group, an isobutyl group, a sec-butyl group, a tert-butyl group, and a 2-ethylhexyl group.

In an embodiment, the linear or branched alkenyl group is a linear alkenyl group having preferably from 2 to 12 carbon atoms, more preferably from 2 to 8 carbon atoms, and even more preferably from 2 to 4 carbon atoms, or is a branched alkenyl group having preferably from 3 to 12 carbon atoms, more preferably from 3 to 8 carbon atoms, and even more preferably from 3 to 6 carbon atoms. Examples of the linear or branched alkenyl group include a vinyl group, a 1-propenyl group, a 2-propenyl group, a 1-butenyl group, a 2-butenyl group, a 3-butenyl group, a 1-pentenyl group, a 2-pentenyl group, a 3-pentenyl group, a 4-pentenyl group, a 1-hexenyl group, a 3-hexenyl group, a 5-hexenyl group, a 1-heptenyl group, a 1-octenyl group, a 1-nonenyl group, a 1-decenyl group, an isopropenyl group, a 2-methyl-1-propenyl group, a methallyl group, a 3-methyl-2-butenyl group, and a 4-methyl-3-pentenyl group.

In an embodiment, the linear or branched alkynyl group is a linear alkynyl group having preferably from 2 to 12 carbon atoms, more preferably from 2 to 8 carbon atoms, and even more preferably from 2 to 4 carbon atoms, or a branched alkynyl group having preferably from 3 to 12 carbon atoms, more preferably from 3 to 8 carbon atoms, and even more preferably from 3 to 6 carbon atoms. Examples of the linear or branched alkynyl group include an ethynyl group, a 1-propynyl group, a 2-propynyl group, a 1-butynyl group, a 2-butynyl group, a 3-butynyl group, a 1-pentynyl group, a 2-pentynyl group, a 3-pentynyl group, a 4-pentynyl group, a 1-hexynyl group, a 2-hexynyl group, a 3-hexynyl group, a 4-hexynyl group, a 5-hexynyl group, a 1-heptynyl group, a 1-octynyl group, a 1-nonynyl group, a 1-decynyl group, a trimethylsilylethynyl group, and a triethylsilylethynyl group.

In an embodiment, the linear or branched alkylidene group is a linear alkylidene group having preferably from 1 to 12 carbon atoms, more preferably from 1 to 8 carbon atoms, and even more preferably from 2 to 4 carbon atoms, or a branched alkylidene group having preferably from 3 to 12 carbon atoms, more preferably from 3 to 8 carbon atoms, and even more preferably from 3 to 6 carbon atoms. Examples of the linear or branched alkylidene group include a methylidene group, a propylidene group, an isopropylidene group, a butylidene group, an isobutylidene group, a sec-butylidene group, a pentylidene group, an isopentylidene group, an octylidene group, and an isooctylidene group.

In an embodiment, examples of the alicyclic hydrocarbon group include a cycloalkyl group and a cycloalkenyl group.

The cycloalkyl group is a cycloalkyl group having preferably from 3 to 12 carbon atoms, more preferably from 4 to 10 carbon atoms, and even more preferably from 5 to 8 carbon atoms. Examples of the cycloalkyl group include a cyclopropyl group, a cyclobutyl group, a cyclopentyl group, a cyclohexyl group, a cycloheptyl group, a cyclooctyl group, a cyclononyl group, and a cyclodecyl group.

The cycloalkenyl group is a cycloalkenyl group having preferably from 3 to 12 carbon atoms, more preferably from 4 to 10 carbon atoms, and even more preferably from 5 to 8 carbon atoms. Examples of the cycloalkenyl group include a cyclopentenyl group and a cyclohexenyl group.

In an embodiment, the aromatic hydrocarbon group is an aryl group having preferably from 6 to 18 carbon atoms, more preferably from 6 to 18 carbon atoms, and even more preferably from 6 to 10 carbon atoms. Examples of the aromatic hydrocarbon group include a phenyl group and a naphthyl group.

A double line including a broken line in Formula (1) represents a single bond or a double bond. When the double line including a broken line is a double bond, R^{c}e is not present, and the nitrogen atom to which R^{a} and R^{b} in Formula (1) are bonded represents an imino group or an N-substituted imino group.

In an embodiment, a total number of amino groups, N-substituted amino groups, and N,N-substituted amino groups that may be included in R^{a} to R^{c} is preferably from 0 to 6, more preferably from 1 to 4, and even more preferably from 1 to 2.

In an embodiment, a total number of imino groups and N-substituted imino groups that may be included in R^{a} to R^{c} is preferably from 0 to 4, more preferably from 1 to 3, and even more preferably from 1 to 2.

In an embodiment, a total number of hydroxyl groups that may be included in R^{a} to R^{c} is preferably from 0 to 6, more preferably from 1 to 4, and even more preferably from 1 to 2.

In an embodiment, a substituent included in the N-substituted amino group, N,N-substituted amino group, and N-substituted imino group is the same as the hydrocarbon group related to R^{a} to R^{c} described above.

In an embodiment, any two of R^{a} to R^{c} may bond to each other and form a ring together with the adjacent nitrogen atom. Examples of the ring to be formed include a pyrrolidine ring, a pyrroline ring, a piperidine ring, a pyrrole ring, an imidazolidine ring, an imidazole ring, a piperazine ring, an imidazolidine ring, a pyridine ring, a diazine ring, and a triazine ring.

In an embodiment, the hydrocarbon group related to R^{a} to R^{c} may have a substituent other than the amino group, the N-substituted amino group, the N,N-substituted amino group, the imino group, the N-substituted imino group, or the hydroxyl group. Examples of such a substituent include halogen atoms (a fluorine atom, a chlorine atom, a bromine atom, and an iodine atom), an oxo group, substituted oxy groups (such as an alkoxy group having from 1 to 4 carbon atoms, an aryl group having from 6 to 10 carbon atoms, an aryloxy group having from 6 to 10 carbon atoms, an aralkyloxy group having from 7 to 16 carbon atoms, and an acyloxy group having from 1 to 4 carbon atoms), a carboxyl group, substituted oxycarbonyl groups (such as an alkoxycarbonyl group having from 1 to 4 carbon atoms, an aryloxycarbonyl group having from 6 to 10 carbon atoms, and an aralkyloxycarbonyl group having from 7 to 16 carbon atoms), a cyano group, a nitro group, a sulfo group, a mercapto group, and a heterocyclic group.

In an embodiment, specific examples of the basic compound represented by Formula (1) include an alkylamine of Formula (1) where at least one of R^{a} to R^{c} is a linear or branched alkyl group; a monoalkanolamine of Formula (1) where R^{a} and R^{b} are hydrogen atoms, and R^{c} is a linear or branched alkyl group having one hydroxyl group; a dialkanolamine of Formula (1) where R^{a} is a hydrogen atom, and R^{b} and R^{c} are the same or different and are linear or branched alkyl groups having one hydroxyl group; a trialkanolamine of Formula (1) where R^{a} to R^{c} are the same or different and are linear or branched alkyl groups having one hydroxyl group; an aminoalkanediol of Formula (1) where R^{a} and R^{b} are the same or different and are hydrogen atoms, or linear or branched alkyl groups, and R^{c} is a linear or branched alkyl group having two hydroxyl groups; a diamine of Formula (1) where R^{a} to R^{c} have a total number of amino group of 1; a triamine of Formula (1) where R^{a} to R^{c} have a total number of amino groups of 2; a diaminoalkanol of Formula (1) where R^{a} to R^{c} have a total number of amino group of 1 and a total number of hydroxyl group of 1; an imidazole compound of Formula (1) where R^{a} to R^{c} have a total number of imino group of 1, and a ring containing the nitrogen atom of the imino group is formed; and nitrogen-containing aromatic compounds of Formula (1) where the nitrogen atom to which R^{a} and R^{b} are bonded is an imino group, and a ring containing the imino group is formed (such as a pyridine-based compound, a diazine-based compound, and a triazine-based compound).

In an embodiment, examples of the alkylamine include methylamine, ethylamine, propylamine, butylamine, pentylamine, dimethylamine, diethylamine, dipropylamine, dibutylamine, dipentylamine, piperidine, trimethylamine, triethylamine, 4-dimethylaminopyridine, 2-aminopyrazine, 2-aminopyrimidine, 3-aminopyridazine, 2-aminotriazine, diazabicyclononene, and diazabicycloundecene.

In an embodiment, examples of the monoalkanolamine include 2-aminoethanol, 3-aminopropanol, 1-amino-2-propanol, 1-amino-2-methyl-2-propanol, 2-amino-2-methyl-1-propanol, 4-amino-i-butanol, 6-amino-i-hexanol, 10-amino-i-decanol, 12-amino-i-dodecanol, N-methyl-2-aminoethanol, N-ethyl-2-aminoethanol, N-propyl-2-aminoethanol, 2-dimethylaminoethanol, 6-diethylaminohexanol, 1-(2-hydroxyethyl)pyrrolidine, 2-(hydroxymethyl)pyrrolidine, 2-(2-hydroxyethyl)-1-methylpyrrolidine, 1-piperidineethanol, and 1-ethanol-4-propanolpiperidine.

In an embodiment, examples of the dialkanolamine include diethanolamine, di-n-propanolamine, diisopropanolamine, di-n-butanolamine, and diisobutanolamine.

In an embodiment, examples of the trialkanolamine include triethanolamine, tri-n-propanolamine, triisopropanolamine, tri-n-butanolamine, and triisobutanolamine.

In an embodiment, examples of the aminoalkanediol include 1-amino-2,3-propanediol, 4-amino-1,2-butanediol, 4-amino-1,3-butanediol, 2-amino-1,3-propanediol, 2-amino-2-methyl-1,3-propanediol, 1-methylamino-2,3-propanediol, 1-ethylamino-2,3-propanediol, 1-propylamino-2,3-propanediol, 1-butylamino-2,3-propanediol, 3-dimethylamino-1,2-propanediol, and 2-diethylamino-1,3-propanediol.

In an embodiment, examples of the diamine include 1,3-propanediamine, 2,2-dimethyl-1,3-propanediamine, 1,4-butanediamine, 1,5-pentanediamine, 1,6-hexanediamine, 1,7-heptanediamine, 1,8-octanediamine, 1,5-diamino-2-methylpentane, N,N′-dimethylethylenediamine, N,N′-diethylethylenediamine, N,N′-dimethyl-1,3-propanediamine, N,N′-diethyl-1,3-propanediamine, N,N′-dimethyl-1,4-butanediamine, N,N′-diethyl-1,4-butanediamine, N,N′-dimethyl-1,6-hexanediamine, N,N-dimethylethylenediamine, N,N-diethylethylenediamine, N,N-dimethyl-1,3-propanediamine, N,N-diethyl-1,3-propanediamine (=diethylaminopropylamine), N,N-dimethyl-1,4-butanediamine, N,N-diethyl-1,4-butanediamine, N,N-dimethyl-1,6-hexanediamine, 1,2-cyclohexanediamine, 1,4-cyclohexanediamine, piperazine, N-methylpiperazine, N-ethylpiperazine, N,N′-dimethylpiperazine, and homopiperazine.

In an embodiment, examples of the triamine include diethylenetriamine, N,N,N′,N″,N″-pentamethyldiethylenetriamine (=pentamethyldiethylenetriamine), N,N,N′,N″,N″-pentakis(2-hydroxypropyl)diethylenetriamine, 3,3′-diaminodipropylamine, N-(3-aminopropyl)-N-methyl-1,3-propanediamine, N′-[3-(dimethylamino)propyl]-N,N-dimethyl-1,3-propanediamine, 2,6,10-trimethyl-2,6,10-triazaundecane, N-(2-aminoethyl)piperazine, 1,4,7-triazacyclononane, N,N,N′,N″,N″-pentakis(2-hydroxypropyl)diethylenetriamine, 1-(2-aminoethyl)-4-methylpiperazine, and 1-(2-dimethylaminoethyl)-4-methylpiperazine.

In an embodiment, examples of the diaminoalkanol include 1,3-diaminopropan-2-ol, 2-(2-aminoethylamino)ethanol, 2-(2-aminopropylamino)ethanol, 2-(2-aminoethylmethylamino)ethanol, 1-(2-hydroxyethyl)piperazine, 4-methylpiperazine-1-ethanol, and 1,4-bis(2-hydroxyethyl)piperazine.

In an embodiment, examples of the imidazole compound include imidazole, 2-methylimidazole, 2-propylimidazole, N-methylimidazole (=1-methylimidazole), N-propylimidazole, N-butylimidazole, 1-(2-hydroxyethyl)imidazole, 2-ethyl-4-methylimidazole, 1,2-dimethylimidazole, 1-benzyl-2-methylimidazole, 1-cyanoethyl-2-methylimidazole, 1-cyanoethyl-2-ethyl-4-methylimidazole, 2-phenyl-4,5-dihydroxymethylimidazole, 1-acetylimidazole, and 2-hydroxybenzimidazole.

In an embodiment, examples of the nitrogen-containing aromatic compound include pyridine, a-picoline, P-picoline, y-picoline, 2,6-lutidine, 2,3-lutidine, pyrazine, 2-hydroxypyrazine, pyrimidine, 2-hydroxypyrimidine, 4-hydroxypyrimidine, pyridazine, 3-hydroxypyridazine, 4-hydroxypyridazine, triazine, and 2-hydroxytriazine.

One type of these may be used alone, or two or more types thereof may be used in combination.

In an embodiment, the molar ratio of the basic group contained in the basic compound to the acidic group contained in the reducing organic substance (basic group/acidic group) is preferably from 0.5 to 1.2, more preferably from 0.55 to 1.15, and even more preferably from 0.6 to 1.1. When the molar ratio is less than 0.5, the storage stability of the copper paste tends to be deteriorated, and when the molar ratio is more than 1.20, a sintered body exhibiting good electrical conductivity tends to be hardly obtained. The number of moles of the basic group in the basic compound is obtained by multiplying the number of moles of the basic compound by the number of basic groups included in the basic compound, and the basic group in the imidazole compound is a group bonding to the nitrogen atom at the 1-position.

### Reducing Organic Substance

The reducing organic substance in the present disclosure is miscible with the following basic compound and serves as a dispersion medium for the metal particles. In addition, the oxide film on surfaces of the metal particles is reduced to promote sintering of the metal particles.

To incorporate the reducing organic substance in the dispersion medium of the present disclosure so that the molar ratio (basic group/acidic group) is from 0.5 to 1.2, the reducing organic substance or a mixed liquid containing the reducing organic substance can be used.

In an embodiment, the reducing organic substance is preferably at least one organic substance selected from formic acid and oxalic acid. Among them, a mixed liquid containing 50 wt. % or more of formic acid is preferable, and an azeotropic formic acid-triethylamine composition (for example, formic acid:triethylamine=5:2 (molar ratio)), an aqueous solution containing 98% formic acid, an aqueous solution containing 88% formic acid, and the like are more preferable, from the viewpoint of easy handling.

In an embodiment, a content of the reducing organic substance in the copper paste is preferably from 6.0 to 22.0 wt. %, more preferably from 6.0 to 20.0 wt. %, and even more preferably from 6.0 to 15.0 wt. %.

In an embodiment, a content of the basic compound in the copper paste is preferably from 3 to 35 wt. %, more preferably from 9.0 to 28.0 wt. %, even more preferably from 9.0 to 25.0 wt. %, and particularly preferably from 9.0 to 20.0 wt. %.

In an embodiment, a weight ratio of the basic compound to the reducing organic substance (basic compound/reducing organic substance) is preferably from 0.4 to 5.0, more preferably from 0.4 to 4.0, and even more preferably from 0.4 to 3.0.

In an embodiment, the dispersion medium may contain water, or an organic solvent other than the mixture of the basic compound and the reducing organic substance (for example, an organic acid other than formic acid (e.g., acetic acid, propionic acid, or n-octanoic acid); an ester-based solvent such as an acetic acid ester (e.g., ethyl acetate or butyl acetate); an ether-based solvent such as dioxane or tetrahydrofuran; a ketone-based solvent such as acetone; an aromatic solvent such as toluene or xylene; a halogen-based solvent such as dichloromethane or chloroform; an alcohol-based solvent such as methanol, ethanol, isopropanol, or butanol; or a nitrile-based solvent such as acetonitrile or benzonitrile), a resin component (for example, a polymer compound having a number average molecular weight of 10000 or more such as an ethyl cellulose resin, an alkyl cellulose resin, a polyvinyl acetal resin, or an acrylic resin), a basic compound other than the basic compound (e.g., an inorganic base (e.g., sodium hydroxide, potassium hydroxide, or ammonia)), an additive (e.g., a surface adjusting agent (a leveling agent), an antifoaming agent, a dispersant, or a thixotropy-imparting agent), or the like in order to adjust fluidity (viscosity) or operability.

In the copper paste for producing a copper pillar for semiconductor connection according to the fourth embodiment, the dispersion medium can be produced through mixing the basic compound and the reducing organic substance with an additional component to form a miscible material.

A temperature at the time of mixing is preferably lower than 100 °C.

Cooling after mixing is any measure that can cool the miscible material to room temperature (e.g., 25 °C) or lower; the miscible material may be gradually cooled at room temperature or rapidly cooled by ice cooling or the like.

In the copper paste according to an embodiment, the content of the basic compound, the content of the reducing organic substance, and the weight ratio (basic compound/reducing organic substance) preferably satisfy the following ranges at the same time from the viewpoint of fillability into a resist opening formed on a semiconductor chip and easily providing a sintered body exhibiting good electrical conductivity.

The content of the reducing organic substance is preferably from 6 to 22 wt. %, more preferably from 6 to 15 wt. %, and even more preferably from 6 to 10 wt. %, and the content of the basic compound (the total content in a case where two or more types of basic compounds are used in combination) is preferably from 3 to 35 wt. %, more preferably from 9 to 28 wt. %, even more preferably from 9 to 20 wt. %, and particularly preferably from 9 to 15 wt. %.

The weight ratio of the basic compound to the reducing organic substance (basic compound/reducing organic substance) is preferably from 0.7 to 3.5, more preferably from 0.72 to 3.4, and even more preferably from 0.74 to 3.3.

A viscosity (25 °C, a shear rate of 10 s⁻¹) of the copper paste according to an embodiment as measured by a rheometer is preferably from 0.1 to 200 Pa·s, more preferably from 0.1 to 100 Pa·s, and even more preferably from 0.1 to 95 Pa·s, from the viewpoint of being capable of improving the fillability into a narrower resist opening formed on a semiconductor chip. In an embodiment, when the viscosity (25 °C, a shear rate of 10 s⁻¹) as measured by a rheometer is from 0.1 to 100 Pa·s, the viscosity may be from 0.2 to 100 Pa·s, and is, for example, preferably from 0.3 to 90 Pa·s.

Examples of a method for adjusting the viscosity of the copper paste include a method of adding water or an organic solvent (excluding a mixture of a basic compound and the reducing organic substance) when the viscosity is too high; a method without adding a resin component or a method of reducing the amount of the resin component to be added; a method of blending an alkylamine having at least one linear alkyl group having from 1 to 20 carbon atoms (preferably from 1 to 15 carbon atoms) together with a chelate-coordinating basic compound as the basic compound; a method of decreasing the content of the copper particles, that is, increasing the proportion of the liquid composition (particularly, the effect is large in a liquid composition having a low viscosity); and a method of increasing the size of the copper particles (since the number of copper particles per weight decreases due to an increase in size of the copper particles, that is, a frequency of collision between the copper particles decreases as a specific surface area decreases).

In the copper paste according to an embodiment, a maximum peak temperature in differential thermogravimetric analysis (DTG), which is a temperature at which a slope of weight loss in thermogravimetric analysis DTG (temperature rising rate: 10 °C/min, in a nitrogen atmosphere) is the largest, is preferably from 100 to 220 °C, more preferably from 110 to 210 °C, and even more preferably from 120 to 200 °C.

### Method for Producing Copper Paste

The copper paste for producing a copper pillar for semiconductor connection according to the fourth embodiment can be produced through mixing copper particles and the dispersion medium. The copper paste of the present disclosure can be produced through mixing copper particles, the basic compound, the reducing organic substance, and an additional component.

A temperature at the time of mixing is preferably lower than 100 °C.

Cooling after mixing is any measure that can cool the copper paste to room temperature (e.g., 25 °C) or lower; the copper paste may be gradually cooled at room temperature or rapidly cooled by ice cooling or the like.

A total content of water, an organic solvent other than the mixture of the basic compound and the reducing organic substance, a basic compound other than the basic compound, an additive, and the like in the copper paste of the present disclosure is preferably 10 wt. % or less.

Since the copper paste of the present disclosure has an appropriate viscosity as described above, the resin component may not be added. Even when the resin component is added, a content of the resin component in the copper paste is preferably 10 wt. % or less, and more preferably 5 wt. % or less. An amount of the resin component to be added, which exceeds the above range, is not preferable since ash originating from the resin component and produced by firing reduces electrical characteristics.

The mixture of the basic compound and the reducing organic substance contained in the copper paste of the present disclosure is quickly volatilized in firing, and further, the reducing organic substance reduces surface oxidation of the metal particles, and thus, even in a non-reducing atmosphere, low-temperature bonding (preferably from 120 to 320 °C, more preferably from 150 to 290 °C, and even more preferably from 180 to 250 °C) of the copper pillars is possible. In an embodiment, the copper pillars formed of the copper paste can be bonded at a temperature of 200 °C or higher and 250 °C or lower. In another embodiment, the copper pillars formed of the copper paste can be bonded at a temperature of lower than 200 °C (more preferably at a temperature of 180 °C). The bonding may be performed in the atmospheric air or in an inert atmosphere (atmosphere of nitrogen, helium, argon, or the like) because the reducing organic substance remains. In order to obtain a further reduced state, firing may be performed in an inert atmosphere together with an additional reducing agent, or may be performed in a reducing atmosphere (for example, a formic acid gas atmosphere).

The copper paste for producing a copper pillar for semiconductor connection according to the fourth embodiment has the above-described characteristics, and thus is suitable for use as a copper paste for producing a copper pillar for semiconductor connection.

In the production of the copper pillar for semiconductor connection according to an embodiment, since the copper pillar has the above-described characteristics, the copper pillar can be formed by patterning on a base material by photolithography using a resist material or laser etching using a thermosetting resin, filling the resulting opening with the copper paste of the present disclosure, and performing temporary drying (200 °C, 10 minutes). Examples of the thermosetting resin include the same ones as those exemplified in the ninth embodiment described later.

In the production of the copper pillar for semiconductor connection according to an embodiment, the opening width of the opening is 80 μm or less, preferably 40 μm or less, more preferably 20 μm or less, and particularly preferably 10 μm or less. In the production of the copper pillar for semiconductor connection according to an embodiment, the opening width of the opening is preferably 40 μm or less.

In the related art, patterning is performed on a base material with a resist resin, and a pillar is formed by copper plating. With the copper paste for producing a copper pillar for semiconductor connection according to the third embodiment, the copper pillar can be formed without using a copper plating method for forming the pillar, and thus the copper pillar can be formed more simply and in fewer steps.

In an embodiment, the copper paste is useful in the production of a semiconductor device because it can bond copper pillars for semiconductor connection to each other at a temperature of from 200 °C to lower than 250 °C, preferably at a temperature of lower than 200 °C, and more preferably at a temperature of 180 °C. The copper paste for producing a copper pillar for semiconductor connection according to the third embodiment eliminates the need for the process conditions of a high temperature of from 300 to 400 °C and a high pressure required for copper-copper bonding of the pillars formed by copper plating to each other, and the bonding temperature for the copper pillars can be lowered to 180 to 250 °C.

When the copper pillars for semiconductor connection are bonded to each other, a liquid composition may be applied to the bonding portion. By applying the liquid composition to the bonding portion, the copper-copper bonding temperature can be further lowered.

### Application

The copper pillar according to the fourth embodiment can be suitably used for a semiconductor device, particularly, as that of a semiconductor device because the number of steps for forming a copper pillar can be reduced as compared with the related art, and the bonding temperature can be lowered.

### Fifth Embodiment: Method for Producing Semiconductor Device

The fifth embodiment relates to a method for producing a semiconductor device, the method including:
forming a resin layer on a substrate or a semiconductor chip using a resin composition;
patterning the resin layer to form a patterned resin layer including an opening; and
filling the opening with a copper paste, particularly, the copper paste described above, to form a copper pillar.

According to the fifth embodiment, the number of steps for forming a copper pillar can be reduced as compared with the related art. In addition, it is possible to provide a method for producing a semiconductor device for producing a pillar for semiconductor connection, which can lower a bonding temperature.

In an embodiment, the method can further include bonding the copper pillars to each other after removing the patterned resin layer.

In an embodiment, the method preferably further includes bonding the patterned resin layers to each other without removing the patterned resin layers, and metal-bonding the copper pillars to each other.

### Polymer Hybrid Bonding

In an embodiment, the copper paste for producing a copper pillar for semiconductor connection according to the fourth embodiment is useful in the method for producing a semiconductor device according to the first embodiment (hereinafter, also referred to as polymer hybrid bonding).

### Sixth Embodiment: Liquid Composition

The sixth embodiment of the present disclosure relates to a liquid composition for assisting in bonding of pillars for semiconductor connection to each other, the liquid composition containing: a reducing organic substance; a basic compound; and a coordinating organic compound excluding a compound included in the basic compound, in which the coordinating organic compound has a boiling point higher than that of the reducing organic substance.

Since the liquid composition contains a reducing organic substance, oxidation of a surface of the pillar for semiconductor connection can be suppressed by applying the liquid composition to the surface of the pillar for semiconductor connection even though firing is not performed in a reducing atmosphere. In addition, since the liquid composition contains a basic compound, a surface of a metal member can be dissolved to remove a metal oxide film, and corrosion of the surface of the pillar for semiconductor connection by the reducing organic substance can be suppressed without removing the liquid composition after it is applied to the surface of the pillar for semiconductor connection. As described above, the liquid composition is suitable as a liquid composition for assisting in bonding of pillars for semiconductor connection to each other.

In the sixth embodiment, the pillar for semiconductor connection means a metal electrode in the form of a protruding fine column (pillar) formed on a semiconductor chip.

In the sixth embodiment, the liquid composition contains a reducing organic substance, a basic compound, and a coordinating organic compound excluding a compound included in the basic compound, and the coordinating organic compound has a boiling point higher than that of the reducing organic substance.

The liquid composition contains a coordinating organic compound, and thus a metal complex is easily formed when the surface of the metal member is dissolved, and further the formed metal complex is easily converted into metal nanoparticles when the metal complex is thermally decomposed or reductively decomposed and deposited on the surface of the metal member. When the metal nanoparticles are present on the surface of the metal member, the influence of surface diffusion increases, and thus the metal member is easily bonded at a lower temperature.

### Reducing Organic Substance

Examples of the reducing organic substance contained in the liquid composition of the sixth embodiment include alcohols (lower alcohols such as ethanol, higher alcohols such as palmitol, and aminoalkanols such as ethanolamine), amino acids, organic acids (such as carboxylic acids), and aromatic compounds (such as polyphenols and phenolic acid compounds). Among these, organic acids (such as carboxylic acids) and aromatic compounds are preferable from the viewpoint of exhibiting acidity, and carboxylic acids are more preferable from the viewpoint that it is liquid at normal temperature, easy to handle, and not highly toxic. One type of these may be used alone, or two or more types thereof may be used.

In an embodiment, examples of the carboxylic acid include formic acid (boiling point: 101 °C), acetic acid (boiling point: 118 °C), lactic acid (boiling point: 122 °C), propionic acid (boiling point: 141 °C), acrylic acid (boiling point: 141 °C), malic acid (boiling point: 167 °C), n-hexanoic acid (boiling point: 205 °C), succinic acid (boiling point: 235 °C), n-octanoic acid (boiling point: 237 °C), tartaric acid (boiling point: 275 °C), and oxalic acid (boiling point: 365 °C), and, among these, formic acid and oxalic acid are preferable from the viewpoint of easily providing a sintered body having excellent reducibility and excellent electrical conductivity.

In an embodiment, the reducing organic substance is preferably formic acid, from the viewpoint that the boiling point is low and that it is easily used in combination with the coordinating organic substance having a boiling point higher than that of the reducing organic substance.

When two or more types of reducing organic substances including formic acid are used in combination as the reducing organic substances, a content of the reducing organic substances other than formic acid is preferably 1 part by mole or less relative to 1 part by mole of formic acid.

### Basic Compound

The basic compound contained in the liquid composition of the sixth embodiment is not particularly limited as long as it functions as a base and realizes the effects of the present disclosure, and specific examples thereof include hydroxides of alkali metals, alkaline earth metals, and the like, nitrogen-containing compounds such as ammonia and amine compounds, and phosphorus-containing compounds such as phosphines and phosphites. Among these, a nitrogen-containing compound represented by Formula (1) below is preferable from the viewpoint of easily providing a sintered body having excellent electrical conductivity.

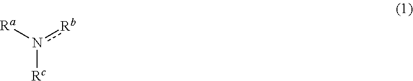

In Formula (1), R^{a} to R^{c} are the same or different and each represent a hydrogen atom or a hydrocarbon group optionally having a substituent. The substituents are the same or different and are each at least one group selected from an amino group, an N-substituted amino group, an N,N-substituted amino group, an imino group, an N-substituted imino group, and a hydroxyl group, provided that R^{a} to R^{c} are not hydrogen atoms at the same time. A double line including a broken line represents a single bond or a double bond, and in the case of a double bond, R^{c} is not present. Any two of R^{a} to R^{c} may bond to each other and form a ring together with the adjacent nitrogen atom.

Examples of the hydrocarbon group related to R^{a} to R^{c} include an aliphatic hydrocarbon group, an alicyclic hydrocarbon group, and an aromatic hydrocarbon group, and, among them, an aliphatic hydrocarbon group and an alicyclic hydrocarbon group are preferable, and an aliphatic hydrocarbon group is more preferable.

Examples of the aliphatic hydrocarbon group include a linear or branched alkyl group, a linear or branched alkenyl group, a linear or branched alkynyl group, and a linear or branched alkylidene group, and, among them, a linear or branched alkyl group is preferable.

The linear or branched alkyl group is a linear alkyl group having preferably from 1 to 20 carbon atoms, and more preferably from 1 to 15 carbon atoms, or a branched alkyl group having preferably from 3 to 12 carbon atoms, more preferably from 3 to 8 carbon atoms, and even more preferably from 3 to 6 carbon atoms. Examples of the linear or branched alkyl group include a methyl group, an ethyl group, a propyl group, a butyl group, a pentyl group, a hexyl group, a decyl group, a dodecyl group, a tetradecyl group, an octadecyl group, an isopropyl group, an isobutyl group, a sec-butyl group, a tert-butyl group, and a 2-ethylhexyl group.

The linear or branched alkenyl group is a linear alkenyl group having preferably from 2 to 12 carbon atoms, more preferably from 2 to 8 carbon atoms, and even more preferably from 2 to 4 carbon atoms, or is a branched alkenyl group having preferably from 3 to 12 carbon atoms, more preferably from 3 to 8 carbon atoms, and even more preferably from 3 to 6 carbon atoms. Examples of the linear or branched alkenyl group include a vinyl group, a 1-propenyl group, a 2-propenyl group, a 1-butenyl group, a 2-butenyl group, a 3-butenyl group, a 1-pentenyl group, a 2-pentenyl group, a 3-pentenyl group, a 4-pentenyl group, a 1-hexenyl group, a 3-hexenyl group, a 5-hexenyl group, a 1-heptenyl group, a 1-octenyl group, a 1-nonenyl group, a 1-decenyl group, an isopropenyl group, a 2-methyl-1-propenyl group, a methallyl group, a 3-methyl-2-butenyl group, and a 4-methyl-3-pentenyl group.

The linear or branched alkynyl group is a linear alkynyl group having preferably from 2 to 12 carbon atoms, more preferably from 2 to 8 carbon atoms, and even more preferably from 2 to 4 carbon atoms, or a branched alkynyl group having preferably from 3 to 12 carbon atoms, more preferably from 3 to 8 carbon atoms, and even more preferably from 3 to 6 carbon atoms. Examples of the linear or branched alkynyl group include an ethynyl group, a 1-propynyl group, a 2-propynyl group, a 1-butynyl group, a 2-butynyl group, a 3-butynyl group, a 1-pentynyl group, a 2-pentynyl group, a 3-pentynyl group, a 4-pentynyl group, a 1-hexynyl group, a 2-hexynyl group, a 3-hexynyl group, a 4-hexynyl group, a 5-hexynyl group, a 1-heptynyl group, a 1-octynyl group, a 1-nonynyl group, a 1-decynyl group, a trimethylsilylethynyl group, and a triethylsilylethynyl group.

The linear or branched alkylidene group is a linear alkylidene group having preferably from 1 to 12 carbon atoms, more preferably from 1 to 8 carbon atoms, and even more preferably from 2 to 4 carbon atoms, or a branched alkylidene group having preferably from 3 to 12 carbon atoms, more preferably from 3 to 8 carbon atoms, and even more preferably from 3 to 6 carbon atoms. Examples of the linear or branched alkylidene group include a methylidene group, a propylidene group, an isopropylidene group, a butylidene group, an isobutylidene group, a sec-butylidene group, a pentylidene group, an isopentylidene group, an octylidene group, and an isooctylidene group.

Examples of the alicyclic hydrocarbon group include a cycloalkyl group and a cycloalkenyl group.

The cycloalkyl group is a cycloalkyl group having preferably from 3 to 12 carbon atoms, more preferably from 4 to 10 carbon atoms, and even more preferably from 5 to 8 carbon atoms. Examples of the cycloalkyl group include a cyclopropyl group, a cyclobutyl group, a cyclopentyl group, a cyclohexyl group, a cycloheptyl group, a cyclooctyl group, a cyclononyl group, and a cyclodecyl group.

The cycloalkenyl group is a cycloalkenyl group having preferably from 3 to 12 carbon atoms, more preferably from 4 to 10 carbon atoms, and even more preferably from 5 to 8 carbon atoms. Examples of the cycloalkenyl group include a cyclopentenyl group and a cyclohexenyl group.

The aromatic hydrocarbon group is an aryl group having preferably from 6 to 18 carbon atoms, more preferably from 6 to 18 carbon atoms, and even more preferably from 6 to 10 carbon atoms. Examples of the aromatic hydrocarbon group include a phenyl group and a naphthyl group.

A double line including a broken line in Formula (1) represents a single bond or a double bond. When the double line including a broken line is a double bond, R^{c} is not present, and the nitrogen atom to which R^{a} and R^{b} in Formula (1) are bonded represents an imino group or an N-substituted imino group.

A total number of amino groups, N-substituted amino groups, and N,N-substituted amino groups that may be included in R^{a} to R^{c} is preferably from 0 to 6, more preferably from 1 to 4, and even more preferably from 1 to 2.

A total number of imino groups and N-substituted imino groups that may be included in R^{a} to R^{c} is preferably from 0 to 4, more preferably from 1 to 3, and even more preferably from 1 to 2.

A total number of hydroxyl groups that may be included in R^{a} to R^{c} is preferably from 0 to 6, more preferably from 1 to 4, and even more preferably from 1 to 2.

A substituent included in the N-substituted amino group, N,N-substituted amino group, and N-substituted imino group is the same as the hydrocarbon group related to R^{a} to R^{c} described above.

Any two of R^{a} to R^{c} may bond to each other and form a ring together with the adjacent nitrogen atom.

Examples of the ring to be formed include a pyrrolidine ring, a pyrroline ring, a piperidine ring, a pyrrole ring, an imidazolidine ring, an imidazole ring, a piperazine ring, an imidazolidine ring, a pyridine ring, a diazine ring, and a triazine ring.

The hydrocarbon group related to R^{a} to R^{c} may have a substituent other than the amino group, the N-substituted amino group, the N,N-substituted amino group, the imino group, the N-substituted imino group, or the hydroxyl group. Examples of such a substituent include halogen atoms (a fluorine atom, a chlorine atom, a bromine atom, and an iodine atom), an oxo group, substituted oxy groups (such as an alkoxy group having from 1 to 4 carbon atoms, an aryl group having from 6 to 10 carbon atoms, an aryloxy group having from 6 to 10 carbon atoms, an aralkyloxy group having from 7 to 16 carbon atoms, and an acyloxy group having from 1 to 4 carbon atoms), a carboxyl group, substituted oxycarbonyl groups (such as an alkoxycarbonyl group having from 1 to 4 carbon atoms, an aryloxycarbonyl group having from 6 to 10 carbon atoms, and an aralkyloxycarbonyl group having from 7 to 16 carbon atoms), a cyano group, a nitro group, a sulfo group, a mercapto group, and a heterocyclic group.

Specific examples of the basic compound represented by Formula (1) include an alkylamine of Formula (1) where at least one of R^{a} to R^{c} is a linear or branched alkyl group; a monoalkanolamine of Formula (1) where R^{a} and R^{b} are hydrogen atoms, and R^{c} is a linear or branched alkyl group having one hydroxyl group; a dialkanolamine of Formula (1) where R^{a} is a hydrogen atom, and R^{b} and R^{c} are the same or different and are linear or branched alkyl groups having one hydroxyl group; a trialkanolamine of Formula (1) where R^{a} to R^{c} are the same or different and are linear or branched alkyl groups having one hydroxyl group; an aminoalkanediol of Formula (1) where R^{a} and R^{b} are the same or different and are hydrogen atoms, or linear or branched alkyl groups, and R^{c} is a linear or branched alkyl group having two hydroxyl groups; a diamine of Formula (1) where R^{a} to R^{c} have a total number of amino group of 1; a triamine of Formula (1) where R^{a} to R^{c} have a total number of amino groups of 2; a diaminoalkanol of Formula (1) where R^{a} to R^{c} have a total number of amino group of 1 and a total number of hydroxyl group of 1; an imidazole compound of Formula (1) where R^{a} to R^{c} have a total number of imino group of 1, and a ring containing the nitrogen atom of the imino group is formed; and nitrogen-containing aromatic compounds of Formula (1) where the nitrogen atom to which R^{a} and R^{b} are bonded is an imino group, and a ring containing the imino group is formed (such as a pyridine-based compound, a diazine-based compound, and a triazine-based compound).

Examples of the alkylamine include methylamine, ethylamine, propylamine, butylamine, pentylamine, dimethylamine, diethylamine, dipropylamine, dibutylamine, dipentylamine, piperidine, trimethylamine, triethylamine, dimethyldodecylamine, 4-dimethylaminopyridine, 2-aminopyrazine, 2-aminopyrimidine, 3-aminopyridazine, 2-aminotriazine, diazabicyclononene, and diazabicycloundecene.

Examples of the monoalkanolamine include 2-aminoethanol, 3-aminopropanol, 1-amino-2-propanol, 1-amino-2-methyl-2-propanol, 2-amino-2-methyl-1-propanol, 4-amino-1-butanol, 6-amino-i-hexanol, 10-amino-i-decanol, 12-amino-i-dodecanol, N-methyl-2-aminoethanol, N-ethyl-2-aminoethanol, 1-dimethylamino-2-propanol, N-propyl-2-aminoethanol, 2-dimethylaminoethanol, 6-diethylaminohexanol, 1-(2-hydroxyethyl)pyrrolidine, 2-(hydroxymethyl)pyrrolidine, 2-(2-hydroxyethyl)-1-methylpyrrolidine, 1-piperidineethanol, and 1-ethanol-4-propanolpiperidine.

Examples of the dialkanolamine include diethanolamine, di-n-propanolamine, diisopropanolamine, di-n-butanolamine, diisobutanolamine, N-methyl-diethanolamine, and N-ethyl-diethanolamine.

Examples of the trialkanolamine include triethanolamine, tri-n-propanolamine, triisopropanolamine, tri-n-butanolamine, and triisobutanolamine.

Examples of the aminoalkanediol include 1-amino-2,3-propanediol, 4-amino-1,2-butanediol, 4-amino-1,3-butanediol, 2-amino-1,3-propanediol, 2-amino-2-methyl-1,3-propanediol, 1-methylamino-2,3-propanediol, 1-ethylamino-2,3-propanediol, 1-propylamino-2,3-propanediol, 1-butylamino-2,3-propanediol, 3-dimethylamino-1,2-propanediol, and 2-diethylamino-1,3-propanediol.

Examples of the diamine include 1,3-propanediamine, 2,2-dimethyl-1,3-propanediamine, 1,4-butanediamine, 1,5-pentanediamine, 1,6-hexanediamine, 1,7-heptanediamine, 1,8-octanediamine, 1,5-diamino-2-methylpentane, N,N′-dimethylethylenediamine, N,N′-diethylethylenediamine, N,N′-dimethyl-1,3-propanediamine, N,N′-diethyl-1,3-propanediamine, N,N′-dimethyl-1,4-butanediamine, N,N′-diethyl-1,4-butanediamine, N,N′-dimethyl-1,6-hexanediamine, N,N-dimethylethylenediamine, N,N-diethylethylenediamine, N,N-dimethyl-1,3-propanediamine, N,N-diethyl-1,3-propanediamine, N,N-dimethyl-1,4-butanediamine, N,N-diethyl-1,4-butanediamine, N,N-dimethyl-1,6-hexanediamine, 1,2-cyclohexanediamine, 1,4-cyclohexanediamine, piperazine, N-methylpiperazine, N-ethylpiperazine, N,N′-dimethylpiperazine, and homopiperazine.

Examples of the triamine include diethylenetriamine, N,N,N′,N″,N″-pentamethyldiethylenetriamine, N,N,N′,N″,N″-pentakis(2-hydroxypropyl)diethylenetriamine, 3,3′-diaminodipropylamine, N-(3-aminopropyl)-N-methyl-1,3-propanediamine, N′-[3-(dimethylamino)propyl]-N,N-dimethyl-1,3-propanediamine, 2,6,10-trimethyl-2,6,10-triazaundecane, N-(2-aminoethyl)piperazine, 1,4,7-triazacyclononane, N,N,N′,N″,N″-pentakis(2-hydroxypropyl)diethylenetriamine, 1-(2-aminoethyl)-4-methylpiperazine, and 1-(2-dimethylaminoethyl)-4-methylpiperazine.

Examples of the diaminoalkanol include 1,3-diaminopropan-2-ol, 2-(2-aminoethylamino)ethanol, 2-(2-aminopropylamino)ethanol, 2-(2-aminoethylmethylamino)ethanol, 1-(2-hydroxyethyl)piperazine, 4-methylpiperazine-1-ethanol, and 1,4-bis(2-hydroxyethyl)piperazine.

Examples of the imidazole compound include imidazole, 2-methylimidazole, 2-propylimidazole, N-methylimidazole, N-propylimidazole, N-butylimidazole, 1-(2-hydroxyethyl)imidazole, 2-ethyl-4-methylimidazole, 1,2-dimethylimidazole, 1-benzyl-2-methylimidazole, 1-cyanoethyl-2-methylimidazole, 1-cyanoethyl-2-ethyl-4-methylimidazole, 2-phenyl-4,5-dihydroxymethylimidazole, 1-acetylimidazole, and 2-hydroxybenzimidazole.

Examples of the nitrogen-containing aromatic compound include pyridine, α-picoline, β-picoline, γ-picoline, 2,6-lutidine, 2,3-lutidine, pyrazine, 2-hydroxypyrazine, pyrimidine, 2-hydroxypyrimidine, 4-hydroxypyrimidine, pyridazine, 3-hydroxypyridazine, 4-hydroxypyridazine, triazine, and 2-hydroxytriazine.

The basic compound contained in the liquid composition according to an embodiment is preferably a chelate-coordinating basic compound having an ethylenediamine structure or an ethanolamine structure in the molecular structure, from the viewpoint of easily stabilizing the metal ion obtained by dissolving the metal oxide on the surface of the pillar for semiconductor connection by chelate coordination. The amino group in the above structure may be any of primary to tertiary amino groups, but is preferably a tertiary amino group from the viewpoint that a side reaction such as amidation between the reducing organic substance and the basic compound is less likely to occur.

A content of the basic compound is preferably from 0.25 to 10 parts by weight, more preferably from 0.5 to 5 parts by weight, and even more preferably from 0.75 to 3 parts by weight, relative to 1 part by weight of the reducing organic substance, from the viewpoint of easily adjusting the ratio of the number of moles (basic group/acidic group) described later.

The basic compound preferably contains an alkylamine having at least one linear alkyl group having from 1 to 20 carbon atoms (preferably from 1 to 15 carbon atoms) together with the chelate-coordinating basic compound, from the viewpoint that the viscosity and wettability of the liquid composition are easily adjusted since it has relatively low polarity. A content of the alkylamine is preferably from 0.01 to 1 part by weight, more preferably from 0.05 to 0.75 parts by weight, and even more preferably from 0.1 to 0.5 parts by weight, relative to 1 part by weight of the reducing organic substance.

One type of the basic compound may be used alone, or two or more types thereof may be used.

In the liquid composition according to an embodiment, a ratio of a total number of moles of the basic groups contained in the basic compound to a total number of moles of the acidic groups contained in the reducing organic substance (basic group/acidic group) is preferably from 0.4 to 2.5, more preferably from 0.45 to 2.4, and even more preferably from 0.5 to 2.3. The total number of moles of the acidic groups contained in the reducing organic substance is obtained by multiplying the number of moles of the reducing organic substance by the number of acidic groups contained in the reducing organic substance, and the total number of moles of the basic groups contained in the basic compound is obtained by multiplying the number of moles of the basic compound by the number of basic groups contained in the basic compound. In an embodiment, the ratio is preferably from 0.7 to 2.5, more preferably more than 1.0 and 2.5 or less, and even more preferably more than 1.0 and 1.5 or less.

### Coordinating Organic Compound

The coordinating organic compound contained in the liquid composition according to the sixth embodiment is a coordinating organic compound excluding a compound included in the basic compound. Since the coordinating organic compound has a boiling point higher than that of the reducing organic substance, the coordinating organic compound is more likely to remain than the reducing organic substance during firing, and contact between the reducing organic substance and an active metal surface is likely to be suppressed, and therefore decomposition of the reducing organic substance is likely to be suppressed.

Examples of the coordinating organic compound include compounds having a carboxyl group (carboxylic acids and the like), compounds having a ketone group (for example, diketones such as acetylacetone, P-ketoesters, and the like), and compounds having a hydroxyl group, a sulfo group, or a thiol group. Among these, a compound having a carboxyl group (a carboxylic acid or the like) is preferable from the viewpoint of easily depositing the dissolved metal oxide as metal nanoparticles.

The compound having a carboxyl group is preferably a monovalent or divalent carboxylic acid, and more preferably a monovalent carboxylic acid from the viewpoint of easy sintering of the deposited metal nanoparticles.

Examples of the carboxylic acid include acetic acid (boiling point: 118 °C), lactic acid (boiling point: 122 °C), propionic acid (boiling point: 141 °C), acrylic acid (boiling point: 141 °C), malic acid (boiling point: 167 °C), n-hexanoic acid (boiling point: 205 °C), succinic acid (boiling point: 235 °C), n-octanoic acid (boiling point: 237 °C), tartaric acid (boiling point: 275 °C), oxalic acid (boiling point: 365 °C), 2-ethylhexanoic acid (boiling point: 227 °C), and caproic acid (boiling point: 205 °C). The carboxylic acid may function as a reducing organic substance or a coordinating organic compound, and thus, when the carboxylic acid is used as the reducing organic substance, another carboxylic acid having a boiling point higher than that of the carboxylic acid may be used in combination as the coordinating organic compound.

The boiling point of the carboxylic acid at normal pressure is preferably higher than 110 °C, more preferably 150 °C or higher, and even more preferably 200 °C or higher, from the viewpoint of being less volatile than formic acid (boiling point: 101 °C).

A content of the coordinating organic compound in the liquid composition according to an embodiment is preferably from 0.05 to 1.00 parts by weight, more preferably from 0.10 to 0.75 parts by weight, and even more preferably from 0.15 to 0.50 parts by weight, relative to 1 part by weight of the reducing organic substance. When the content is 0.05 parts by weight or more, the metal nanoparticles are easily deposited, and when the content is 1.00 parts by weight or less, the liquid composition is less likely to remain during firing.

In the liquid composition according to an embodiment, the molar ratio of the coordinating organic compound to the basic compound (coordinating organic compound/basic compound) is preferably from 0.01 to 1.00, more preferably from 0.05 to 0.50, and even more preferably from 0.10 to 0.40. When the molar ratio is 0.01 or more, the metal nanoparticles are easily deposited, and when the molar ratio is 1.00 or less, the liquid composition is less likely to remain during firing.

### Solvent

The liquid composition according to an embodiment may contain a solvent such as water or an organic solvent in addition to the basic compound, the reducing organic substance, and the coordinating organic compound described above in order to adjust the fluidity (viscosity) and the operability. Examples of the organic solvent include ester-based solvents such as acetic acid esters (such as ethyl acetate and butyl acetate) and ester oils (such as butyl stearate, hexyl laurate, and triethyl citrate); ether-based solvents such as dioxane and tetrahydrofuran; ketone-based solvents such as acetone; aromatic solvents such as toluene and xylene; halogen-based solvents such as dichloromethane and chloroform; alcohol-based solvents such as methanol, ethanol, isopropanol, and butanol; and nitrile-based solvents such as acetonitrile and benzonitrile. One type of these may be used alone, or two or more types thereof may be used.

A content of the solvent is preferably from 0 to 200 parts by weight, more preferably from 0.10 to 100 parts by weight, even more preferably from 0.20 to 40 parts by weight, particularly preferably from 0.50 to 10 parts by weight, most preferably from 1 to 5 parts by weight, relative to 1 part by weight of the reducing organic substance.

The liquid composition according to an embodiment may contain an additional component such as a resin component (for example, a polymer compound having a number average molecular weight of 10000 or more such as an ethyl cellulose resin, an alkyl cellulose resin, a polyvinyl acetal resin, or an acrylic resin) or an additive (a surface adjusting agent, a leveling agent, an antifoaming agent, a dispersant, a thixotropy-imparting agent, or the like) as long as the effects of the present disclosure are not impaired. A content of the additional component in the liquid composition is, for example, 1 wt. % or less (preferably 0.5 wt. % or less).

### Method for Producing Liquid Composition

The liquid composition according to the sixth embodiment can be produced through mixing the basic compound, the reducing organic substance, and the coordinating organic compound described above, as well as the solvent and the additional component described above.

A temperature at the time of mixing is preferably lower than 100 °C.

Cooling after mixing is any measure that can cool the liquid composition to room temperature (e.g., 25 °C) or lower; the liquid composition may be gradually cooled at room temperature or rapidly cooled by ice cooling or the like.

### Method for Producing Solvent-Treated Pillar for Semiconductor Connection

By applying the liquid composition according to the sixth embodiment to the pillar for semiconductor connection, a solvent-treated pillar for semiconductor connection can be produced. In the solvent-treated pillar for semiconductor connection, the metal oxide film on the surface is dissolved and removed by the liquid composition. When the solvent-treated pillar for semiconductor connection is used, a sintered body and a bonded body having excellent electrical conductivity can be produced by the liquid composition remaining on the surface during firing even in a non-reducing atmosphere.

In addition, by applying the liquid composition according to the sixth embodiment to the pillar for semiconductor connection, a solvent-treated pillar for semiconductor connection having a surface of the pillar for semiconductor connection on which a metal oxide film is dissolved and removed and metal nanoparticles having a number average particle size of less than 600 nm (1 nm or more and less than 600 nm, 5 nm or more and less than 100 nm, or 10 nm or more and less than 60 nm) are deposited. That is, when the liquid composition according to the sixth embodiment is used, a pillar for semiconductor connection having metal nanoparticles on a surface thereof can be produced by applying the liquid composition to the pillar for semiconductor connection, dissolving at least a part of the surface of the pillar for semiconductor connection to form a metal complex, and thermally decomposing and/or reductively decomposing the formed metal complex to deposit metal nanoparticles on the surface of the pillar for semiconductor connection. The thermal decomposition and/or reductive decomposition is achieved by heating in the presence of the reducing organic substance. The metal member has metal nanoparticles on a surface thereof, and therefore can be fired at a lower temperature. A number average particle size of the metal nanoparticles can be calculated on a number basis by, for example, electron microscope observation.

Examples of the metal forming the pillar for semiconductor connection include gold, silver, copper, nickel, palladium, tin, aluminum, and alloys thereof. Among these, copper and silver are likely to form a metal oxide film on the surface, and therefore, when the liquid composition is used, an improvement effect of obtaining a sintered body and a bonded body having excellent electrical conductivity becomes remarkable.

The shape of the metal particles contained in an aggregate which is the pillar for semiconductor connection may be various shapes such as a spherical shape, an ellipsoidal flake shape (flat shape), and a short fiber shape, and may be an indefinite shape. One type of these may be used alone, or two or more types thereof may be used.

A volume average particle size (median diameter, D₅₀) of the metal particles used for forming the aggregate which is the pillar for semiconductor connection may be, for example, from 1 nm to 100 μm, and may be 600 nm or more (from 600 nm to 100 μm, or from 1 to 10 μm) because the metal nanoparticles are deposited when a second liquid composition is applied. The average particle size of the metal particles can be measured, for example, by a laser diffraction/scattering method.

In the production of the solvent-treated pillar for semiconductor connection, an amount of the metal nanoparticles to be deposited can be adjusted by separately dissolving a metal compound in the liquid composition according to the sixth embodiment and then applying the liquid composition.

As the metal compound to be dissolved, a metal compound containing copper is preferable from the viewpoint of depositing copper nanoparticles that are easily sintered, and copper (II) oxide, cuprous (I) oxide, and copper (II) hydroxide are more preferable from the viewpoint of saving time and effort for storage. One type of these may be used alone, or two or more types thereof may be used.

A sintered body can be obtained by heating the solvent-treated pillar for semiconductor connection obtained by the above production method, and a bonded body can be obtained by heating the solvent-treated metal member and the member to be bonded in contact with each other.

The bonded body may be obtained by applying the liquid composition according to the sixth embodiment to an aggregate layer of metal particles formed on a surface of a base material to form a treated aggregate layer, and then bringing a member to be bonded and the treated aggregate layer into contact with each other and heating the member to be bonded and the treated aggregate layer to bond the base material and the member to be bonded.

The heating can be performed, for example, within a temperature range of from 200 to 250 °C, preferably lower than 200 °C. A heating time may be, for example, from 1 to 120 minutes (or from 5 to 60 minutes). In addition, a bonding surface of the bonded body (laminate) may be pressurized at a pressure of 20 MPa or less, for example.

### Use of Liquid Composition for Assisting in Bonding of Pillars for Semiconductor Connection to Each Other

The liquid composition for assisting in bonding of pillars for semiconductor connection to each other according to the sixth embodiment has the above characteristics, and is therefore suitable for use in assisting in bonding of pillars for semiconductor connection to each other.

In the bonding of copper pillars for semiconductor connection according to an embodiment, when the copper pillars for semiconductor connection are bonded to each other, the bonding temperature can be lowered to 200 °C by applying the liquid composition for assisting in bonding of pillars for semiconductor connection to each other according to the sixth embodiment to the bonding portion.

In the bonding of pillars for semiconductor connection according to an embodiment, the opening width of the opening is preferably less than 40 μm.

In the related art, for example, since process conditions of a high temperature of from 300 to 400 °C and a high pressure are required for copper-copper bonding of pillars formed by copper plating, warpage of a base material and influence on other members are large, but the liquid composition for assisting in bonding of pillars for semiconductor connection to each other according to the sixth embodiment can lower the bonding temperature to 200 °C, and thus, a semiconductor device can be produced with less warpage of a base material and influence on other members.

### Polymer Hybrid Bonding

In an embodiment, the liquid composition for producing a copper pillar for semiconductor connection according to the sixth embodiment is useful in the method for producing a semiconductor device according to the first embodiment (hereinafter, also referred to as polymer hybrid bonding).

### Eighth Embodiment: Method for Producing Semiconductor Device

The eighth embodiment of the present disclosure relates to a method for producing a semiconductor device, the method including:
a first step of applying a photosensitive resin composition on a base material or a semiconductor chip;
a second step of patterning the photosensitive resin composition by photolithography with a maximum interval width being 80 μm or less;
a third step of filling an opening formed by the patterning with a copper paste and drying the copper paste to form a copper pillar;
a fourth step of planarizing a surface having the copper pillar and the patterning without peeling off the photosensitive resin composition; preparing a set of structures obtained through the first step to the fourth step;
a fifth step of applying a liquid composition to the planarized surface of at least one of the set of structures;
a sixth step of stacking the set of structures with the copper pillars being in contact with each other; and
a seventh step of heating the set of structures at 200 °C or lower in an inert atmosphere.

In an embodiment, from the viewpoint of enabling patterning at a narrower pitch, the photosensitive resin composition in the eighth embodiment is preferably the photosensitive resin composition according to the third embodiment.

In an embodiment, from the viewpoint of lowering the bonding temperature between the structures, the copper paste in the eighth embodiment is preferably the copper paste according to the fourth embodiment.

In an embodiment, from the viewpoint of lowering the bonding temperature between the structures, the liquid composition in the eighth embodiment is preferably the liquid composition according to the sixth embodiment.

### Ninth Embodiment: Method for Producing Semiconductor Device

In the embodiments described above, the example in which the metal pillar is formed in the opening of the patterned resin layer has been described, but the resin may be applied after the metal pillar is formed.

The ninth embodiment of the present disclosure relates to a method for producing a semiconductor device, the method including:
a first step of applying a thermosetting resin onto a base material or a semiconductor chip on which metal pillars are formed at a pitch with a maximum width of an interval of 80 μm or less;
a second step of planarizing a surface having the metal pillars and the thermosetting resin; preparing a set of structures obtained through the first step and the second step;
a third step of applying a liquid composition to the planarized surface of the metal pillars of at least one of the set of structures;
a fourth step of stacking the set of structures with the metal pillars being in contact with each other; and
a fifth step of heating the set of structures at 200 °C or lower (preferably from 150 to 200 °C, for example, 200 °C) in an inert atmosphere.

According to the ninth embodiment, the number of production steps can be reduced as compared with the related art (the copper pillar formation, the resin peeling, the re-application, and the like are not required), and the bonding temperature between the structures having the metal pillars can be further lowered as compared with the related art.

In an embodiment, from the viewpoint of adhesiveness to a base material or a semiconductor chip, the thermosetting resin according to the ninth embodiment is preferably a thermosetting composition containing a compound (A) represented by Formula (X) below and a silsesquioxane (B) which is one or more selected from the group consisting of a random silsesquioxane (B1) and a silsesquioxane (B2) having a ladder skeleton and has a constituent unit represented by Formula (Y) below.

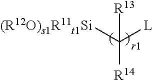

where r1 represents an integer of from 4 to 20; L represents a group containing one or more groups selected from the group consisting of an epoxy group, an oxetanyl group, and a vinyl ether group; R¹¹ and R¹² each represent a hydrocarbon group which may have a substituent; s1 represents an integer of from 1 to 3, t1 represents an integer of from 0 to 2, and s1+t1 is 3; and R¹³ and R¹⁴ each represent a hydrogen atom, or a hydrocarbon group that may have a substituent.

[R¹SiO_{3/2}](Y)
where R¹ represents a group containing an epoxy group.

In an embodiment, from the viewpoint of the adhesion between the thermosetting resin and the base material or the semiconductor chip, it is preferable to apply a surface treatment agent onto the base material or the semiconductor chip before applying the thermosetting resin onto the base material or the semiconductor chip.

In an embodiment, from the viewpoint of lowering the bonding temperature between the structures, the liquid composition in the ninth embodiment is preferably the liquid composition according to the sixth embodiment.

As a method for producing a metal pillar in the method for producing a semiconductor device according to the present embodiment, a typically known method can be adopted, but, in the production method of the present embodiment, the interval of patterning is narrow, and thus it is preferable to adopt the method for forming a metal pillar using the copper paste for producing a copper pillar for semiconductor connection of the fourth embodiment.

### EXAMPLE

The present embodiments will be described below in more detail by way of examples, but the interpretation of the present invention is not limited by the examples.

### (1) Polymer (A) and (2) Photosensitive Resin Composition

In the synthesis of a polymer (A), the following monomers were used.
Methacrylic acid (MAA)
4-Hydroxyphenyl methacrylate (PQMA)
N-cyclohexylmaleimide (CHMI)
Butyl acrylate (BA)
p-Isopropenylphenol (IPP)

### Example 1

### Synthesis of Polymer (A) [MAA/PQMA/CHMI/BA=11/14/40/35 wt. %, Mw=10000, NV=30 wt. %]

An appropriate amount of nitrogen was introduced into a 1-L flask equipped with a reflux condenser, a dropping funnel, and a stirrer to form a nitrogen atmosphere, and 201 g of propylene glycol monomethyl ether acetate was put therein, and heated to 80 °C with stirring. Thereafter, a mixed solution of a solution obtained by dissolving 96 g (0.53 mol) of N-cyclohexylmaleimide, 84 g (0.65 mol) of butyl acrylate, 34 g (0.19 mol) of 4-hydroxyphenyl methacrylate, and 26 g (0.30 mol) of methacrylic acid as monomers in 222 g of propylene glycol monomethyl ether acetate, and a solution obtained by dissolving 22 g of 2,2′-azobis(2,4-dimethylvaleronitrile) and 2 g of 2,2-azobisisobutyronitrile in 114 g of propylene glycol monomethyl ether acetate was added dropwise over about 5 hours using a dropping pump. After completion of the dropwise addition of the mixed solution, the temperature was maintained at the same temperature for about 3 hours, and then cooled to room temperature to obtain a solution (P-1) of a polymer (A) having a solid content of 31.1 wt. %. The produced copolymer had a weight average molecular weight Mw of 10000, a degree of dispersion of 1.90, and an acid number of 70 KOHmg/g.

### Preparation of Photosensitive Resin Composition

In a flask, 12.8 g of the polymer solution (P-1) of the polymer (A), 6.4 g of polyester acrylate (ARONIX M-8060 available from Toagosei Co., Ltd.), 0.51 g of diphenyl (2,4,6,-trimethoxybenzoyl) phosphineoxide, 0.051 g of 6-[1-(acetyloxyimino)ethyl]-9-ethyl-9H-carbazol-3-yl(2-methylphenyl)ketone, and 12.8 g of propylene glycol monomethyl ether acetate were charged, and heated to 40 °C with stirring. Thereafter, the mixture was filtered through a propylene filter (sieve opening: 10 μm) with a pressure filtering machine at 0.1 MPa to obtain a photosensitive resin composition (R-1).

### Comparative Example 1

### Synthesis of Polymer (MAA/IPP/CHMI/BA=11/14/40/35 wt. %, Mw=10000, NV=30 wt. %

An appropriate amount of nitrogen was introduced into a 1-L flask equipped with a reflux condenser, a dropping funnel, and a stirrer to form a nitrogen atmosphere, and 184 g of propylene glycol monomethyl ether acetate was put therein, and heated to 80 °C with stirring. Thereafter, a mixed solution of a solution obtained by dissolving 106 g of N-cyclohexylmaleimide, 92 g of butyl acrylate, 37 g of p-isopropenylphenol and 29 g of methacrylic acid as monomers in 214 g of propylene glycol monomethyl ether acetate, and a solution obtained by dissolving 22 g of 2,2′-azobis(2,4-dimethylvaleronitrile) and 2 g of 2,2-azobisisobutyronitrile in 114 g of propylene glycol monomethyl ether acetate was added dropwise over about 5 hours using a dropping pump. After completion of the dropwise addition of the mixed solution, the temperature was maintained at the same temperature for about 3 hours, and then cooled to room temperature to obtain a polymer solution (P-2) having a solid content of 34.3 wt. %. The produced copolymer had a weight average molecular weight Mw of 9900, a degree of dispersion of 1.80, and an acid number of 73 KOHmg/g.

### Preparation of Photosensitive Resin Composition

In a flask, 12.8 g of the polymer solution (P-2), 6.4 g of polyester acrylate (ARONIX M-8060 available from Toagosei Co., Ltd.), 0.51 g of diphenyl (2,4,6,-trimethoxybenzoyl) phosphineoxide, 0.051 g of 6-[1-(acetyloxyimino)ethyl]-9-ethyl-9H-carbazol-3-yl(2-methylphenyl)ketone, and 12.8 g of propylene glycol monomethyl ether acetate were charged, and heated to 40 °C with stirring. Thereafter, the mixture was filtered through a propylene filter (sieve opening: 10 μm) with a pressure filtering machine at 0.1 MPa to obtain a photosensitive resin composition (R-2).

### Evaluation of Patterning

The photosensitive resin compositions (R-1) and (R-2) according to Example 1 and Comparative Example 1 were each applied onto a semiconductor chip (Si base material), and a patterning was formed at as narrow intervals as possible by photolithography under the following conditions.

An Si substrate coated with the photosensitive resin composition was prebaked at 120 °C for 5 minutes, and then exposed to broadband light having a central wavelength of 405 nm at an irradiation intensity of 1800 mJ/cm² through a predetermined pattern mask. After the exposure, the coating film was brought into contact with a 2.38 mass % aqueous tetramethylammonium hydroxide solution for 240 seconds, washed with running water and developed to perform patterning.

In the case of the photosensitive resin composition (R-1) according to Example 1, the maximum width of the pitch (interval) between adjacent openings was 20 μm.

In the case of the photosensitive resin composition (R-2) according to Comparative Example 1, the maximum width of the pitch (interval) between adjacent openings was 40 μm.

From the above, it was found that a patterning can be formed at a narrower pitch by using the polymer (A) according to the second embodiment and the photosensitive resin composition according to the third embodiment.

### Evaluation of Adhesiveness

The photosensitive resin composition (R-1) according to Example 1 was applied onto an Si wafer, then prebaked at 120 °C for 5 minutes, and exposed to broadband light having a central wavelength of 405 nm at an irradiation intensity of 1800 mJ/cm². After the exposure, the coating film was brought into contact with a 2.38 mass % aqueous tetramethylammonium hydroxide solution for 240 seconds, and washed with running water, thereby forming a photosensitive resin composition-coated substrate subjected to exposure and development treatments. The photosensitive resin composition-coated substrate was cut into a size of 20 mm×20 mm with a diamond cutter, and an Si wafer cut into a size of 3 mm×3 mm was mounted on a resin composition surface of the cut substrate, followed by heating at 250 °C for 10 minutes under a load of 0.19 MPa, to produce a laminate for evaluation of adhesiveness. The heating rate and the cooling rate were 10 °C/sec.

When a cross section of the laminate for evaluation was observed with SEM, no peeling was observed at an interface between the Si wafer and the photosensitive resin composition (R-1), and it was found that the photosensitive resin composition (R-1) could be used as an adhesive layer even after the exposure and development treatments.

When a pair of copper bumps according to Example 1 were bonded to each other, sufficient bonding strength was obtained between the copper bumps. On the other hand, when a pair of copper bumps according to Comparative Example 1 were bonded to each other, the copper bumps could not be bonded to each other.

From the above, a patterning can be formed at a narrower pitch by using the polymer (A) according to the second embodiment and the photosensitive resin composition according to the third embodiment. Further, after patterning, the resist resin can be used as a resist resin adhesive layer without peeling off the resist resin and without using an adhesive layer separately from the resist resin. It was found that this can eliminate the peeling off the resist resin, the applying an adhesive layer separately from the resist resin, the filling an underfiller, and the like. That is, it was found that the number of steps can be reduced by the method for producing a semiconductor device according to the first embodiment as compared with the related art.

### (3) Copper Paste

Hereinafter, a volume average particle size (median diameter, D50) of the metal particles is a value as measured by a laser diffraction/scattering method unless otherwise specified. The copper particles, formic acids, basic compounds, and additional additives used are as follows.

### Copper Particle

TNCu: volume average particle size: 110 nm (calculated by an SEM observation method), available from Taiyo Nippon Sanso Corporation
CH-0200L1: volume average particle size: 200 nm, available from Mitsui Mining and Smelting Company, Limited
1100Y: volume average particle size: 1.1 μm, available from Mitsui Mining and Smelting Company, Limited

### Formic Acid

Formic acid: available from FUJIFILM Wako Pure Chemical Corporation
Formic acid/triethylamine (azeotropic composition at a molar ratio of 5:2): available from Tokyo Chemical Industry Co., Ltd.

### Basic Compound

Triethanolamine: reagent available from Tokyo Chemical Industry Co., Ltd.
1-Methylimidazole: reagent available from Tokyo Chemical Industry Co., Ltd.
Pentamethyldiethylenetriamine: reagent available from Tokyo Chemical Industry Co., Ltd.
N-ethyldiethanolamine: reagent available from Tokyo Chemical Industry Co., Ltd.
Diethanolamine: reagent available from Tokyo Chemical Industry Co., Ltd.

### Additional Additive

Ethylene glycol: reagent available from Tokyo Chemical Industry Co., Ltd.
PVP K30: available from FUJIFILM Wako Pure Chemical Corporation
Water

### Peak Temperature at Which Slope of Weight Loss is Largest (DTG Maximum Peak Temperature)

A differential thermogravimetric (DTG) curve was obtained by differentiating a TG curve obtained by thermogravimetric measurement under conditions of a nitrogen atmosphere (flow rate: 200 ml/min) and a temperature rising rate of 10 °C/min using a thermogravimetric analyzer (TG-DSC, STA200, available from Hitachi High-Tech Science Corporation), and a peak having a largest value in the negative direction was defined as the DTG maximum peak.

### Viscosity of Copper Paste

For an evaluation sample of the copper paste, a viscosity curve was obtained using a rheometer (MCR302, available from Anton Paar GmbH) with CP25-2 as a measuring jig under the condition of 25 °C while changing the shear rate from 0.01 to 1000 s⁻¹ in logarithmic increments. From the obtained viscosity curve, the shear viscosity at the shear rate of 10 s⁻¹ was defined as the viscosity of the copper paste. The results are shown in Table 1.

### Example 2

Ethylene glycol and PVP K30 were mixed to achieve the contents shown in Table 1, and the mixture was stirred at 60 °C for 60 minutes to completely dissolve PVP K30, thereby obtaining a resin solution. Thereafter, the resin solution, formic acid, oxalic acid, N-ethyldiethanolamine, and TNCu were mixed to achieve the contents shown in Table 1, and the mixture was stirred for 2 minutes using a planetary centrifugal mixer (Awatori Rentaro, available from Thinky Corporation) to produce a copper paste. The molar ratio between formic acid and basic groups was 0.67. The DTG maximum peak temperature was 194 °C. The viscosity of the copper paste was 121 Pa·s, and the copper paste was not increased in viscosity even after being stored under a nitrogen-sealed condition at 5 °C or 25 °C for 1 week, and was also excellent in storage stability.

A sample (S-1) for producing a copper pillar in which the interval of patterning was set to 40 μm and a sample (S-2) for producing a copper pillar in which the interval of patterning was set to 20 μm were produced by the same method as the patterning evaluation in Example 1 using the photosensitive resin composition (R-1) according to Example 1. The paste of Example 1 was filled into the opening of each of the samples (S-1) and (S-2) for pillar production using an applicator. The copper paste was filled into (S-1), and thus a copper pillar could be produced. The copper paste was not filled into (S-2), and no copper pillar could be produced.

### Example 3

Formic acid, pentamethyldiethylenetriamine, and CH-0200L1 were mixed to achieve the contents shown in Table 1, and the mixture was stirred for 2 minutes using a planetary centrifugal mixer (Awatori Rentaro, available from Thinky Corporation) to produce a copper paste. The molar ratio between formic acid and basic groups was 0.52. The DTG maximum peak temperature was 135 °C. The viscosity of the copper paste was 89.7 Pa·s, and the copper paste was not increased in viscosity even after being stored under a nitrogen-sealed condition at 5 °C or 25 °C for 1 week, and was also excellent in storage stability.

When a copper pillar was produced in the same manner as in Example 2 except that the paste of Example 3 was used, copper pillars were produced for both (S-1) and (S-2).

### Example 4

Formic acid, pentamethyldiethylenetriamine, N-ethyldiethanolamine, and CH-0200L1 were mixed to achieve the contents shown in Table 1, and the mixture was stirred for 2 minutes using a planetary centrifugal mixer (Awatori Rentaro, available from Thinky Corporation) to produce a copper paste. The molar ratio between formic acid and basic groups was 0.55. The DTG maximum peak temperature was 135 °C. The viscosity of the copper paste was 11 Pa·s, and the copper paste was not increased in viscosity even after being stored under a nitrogen-sealed condition at 5 °C or 25 °C for 1 week, and was also excellent in storage stability.

When a copper pillar was produced in the same manner as in Example 2 except that the paste of Example 4 was used, copper pillars were produced for both (S-1) and (S-2).

### Example 5

Ethylene glycol and PVP K30 were mixed to achieve the contents shown in Table 1, and the mixture was stirred at 60 °C for 60 minutes to completely dissolve PVP K30, thereby obtaining a resin solution. Thereafter, the resin solution, formic acid, oxalic acid, pentamethyldiethylenetriamine, N-ethyldiethanolamine, TNCu, and 1100Y were mixed to achieve the contents shown in Table 1, and the mixture was stirred for 2 minutes using a planetary centrifugal mixer (Awatori Rentaro, available from Thinky Corporation) to produce a copper paste. The molar ratio between formic acid and basic groups was 1.13. The DTG maximum peak temperature was 194 °C. The viscosity of the copper paste was 11 Pa·s, and the copper paste was not increased in viscosity even after being stored under a nitrogen-sealed condition at 5 °C or 25 °C for 1 week, and was also excellent in storage stability.

When a copper pillar was produced in the same manner as in Example 2 except that the paste of Example 5 was used, copper pillars were produced for both (S-1) and (S-2).

### Example 6

Formic acid, pentamethyldiethylenetriamine 1-methylimidazole, N-ethyldiethanolamine, and CH-0200L1 were mixed to achieve the contents shown in Table 1, and the mixture was stirred for 2 minutes using a planetary centrifugal mixer (Awatori Rentaro, available from Thinky Corporation) to produce a copper paste. The molar ratio between formic acid and basic groups was 1.13. The DTG maximum peak temperature was 135 °C. The viscosity of the copper paste was 0.3 Pa·s. The copper paste was not increased in viscosity even after being stored under a nitrogen-sealed condition at 5 °C or 25 °C for 1 week, and was also excellent in storage stability.

When a copper pillar was produced in the same manner as in Example 2 except that the paste of Example 6 was used, copper pillars were produced for both (S-1) and (S-2).

### Comparative Example 2

A formic acid/triethylamine mixed solvent (5:2 molar ratio azeotropic composition), triethanolamine, and TNCu were blended to achieve the contents shown in Table 1, and the mixture was stirred for 5 minutes using a planetary centrifugal mixer (Awatori Rentaro, available from Thinky Corporation) to produce a paste. The molar ratio between formic acid and basic groups (basic group/formic acid) was 0.96. The DTG maximum peak temperature was 130 °C. The viscosity of the paste of Example 2 was 239 Pa·s, and the paste was not increased in viscosity even after being stored under a nitrogen-sealed condition at 5 °C or 25 °C for 1 week, and was also excellent in storage stability.

When a copper pillar was produced in the same manner as in Example 2 except that the paste of Comparative Example 2 was used, the copper paste could be filled into neither (S-1) nor (S-2), and no copper pillar could be produced.

### Comparative Example 3

Formic acid, 1-methylimidazole, water, and TNCu were mixed to achieve the contents shown in Table 1, and the mixture was stirred for 2 minutes using a planetary centrifugal mixer (Awatori Rentaro, available from Thinky Corporation) to produce a copper paste. The molar ratio between formic acid and basic groups was 1.13. The DTG maximum peak temperature was 135 °C. The viscosity of the copper paste was 0.3 Pa·s, and the copper paste was not increased in viscosity even after being stored under a nitrogen-sealed condition at 5 °C or 25 °C for 1 week, and was also excellent in storage stability.

When a copper pillar was produced in the same manner as in Example 2 except that the paste of Comparative Example 3 was used, the copper paste could be filled into neither (S-1) nor (S-2), and no copper pillar could be produced.

### Comparative Example 4

Formic acid, triethylamine, and TNCu were mixed to achieve the contents shown in Table 1, and the mixture was stirred for 2 minutes using a planetary centrifugal mixer (Awatori Rentaro, available from Thinky Corporation) to produce a copper paste. The molar ratio between formic acid and basic groups was 0.4. The DTG maximum peak temperature was 123 °C. The viscosity of the copper paste was 66 Pa·s. After storage for 1 week under a nitrogen-sealed condition at 5 °C or 25 °C, the viscosity significantly increased and the storage stability was poor.

When a copper pillar was produced in the same manner as in Example 2 except that the paste of Comparative Example 4 was used, copper pillars were produced for both (S-1) and (S-2).

### Comparative Example 5

Formic acid, 1-methylimidazole, water, and TNCu were mixed to achieve the contents shown in Table 1, and the mixture was stirred for 2 minutes using a planetary centrifugal mixer (Awatori Rentaro, available from Thinky Corporation) to produce a copper paste. The molar ratio between formic acid and basic groups was 0.4. The DTG maximum peak temperature was 117 °C. The viscosity of the copper paste was 403 Pa·s. After storage for 1 week under a nitrogen-sealed condition at 5 °C or 25 °C, the viscosity significantly increased and the storage stability was poor.

When a copper pillar was produced in the same manner as in Example 2 except that the paste of Comparative Example 5 was used, the copper paste could be filled into neither (S-1) nor (S-2), and no copper pillar could be produced.

### Comparative Example 6

Formic acid, 1-methylimidazole, N-ethyldiethanolamine, water, and TNCu were mixed to achieve the contents shown in Table 1, and the mixture was stirred for 2 minutes using a planetary centrifugal mixer (Awatori Rentaro, available from Thinky Corporation) to produce a copper paste. The molar ratio between formic acid and basic groups was 1.31. The DTG maximum peak temperature was 136 °C. The viscosity of the copper paste was 245 Pa·s, and the copper paste was not increased in viscosity even after being stored under a nitrogen-sealed condition at 5 °C or 25 °C for 1 week, and was also excellent in storage stability.

When a copper pillar was produced in the same manner as in Example 2 except that the paste of Comparative Example 3 was used, the copper paste could be filled into neither (S-1) nor (S-2), and no copper pillar could be produced.

As described above, the copper paste according to the fourth embodiment can reduce the number of steps for forming a copper pillar as compared with the related art. In addition, the bonding temperature can be lowered. Further, the copper paste according to the fourth embodiment can provide high fillability even when the resist opening formed on the semiconductor chip is narrow.

TABLE 1

| | | | | | | | Compar- | Compar- | Compar- | Compar- | Compar- |
|---|---|---|---|---|---|---|---|---|---|---|---|
| | | Exam- | Exam- | Exam- | Exam- | Exam- | ative | ative | ative | ative | ative |
| (wt. %) | | ple 2 | ple 3 | ple 4 | ple 5 | ple 6 | Example 2 | Example 3 | Example 4 | Example 5 | Example 6 |
| Copper | TNCu | 72 | | | 63.9 | | 80 | 83.4 | 80 | 83.3 | 83.3 |
| particle | CH-0200L1 | | 83 | 80 | | 55 | | | | | |
| | 1100Y | | | | 8.1 | | | | | | |
| Reducing | Formic acid | 1.8 | 7.4 | 7.6 | 1.8 | 13 | 5.4 | 7.5 | 10.6 | 9 | 3.8 |
| organic | Oxalic acid | 4.4 | | | 4.4 | | | | | | |
| substance | | | | | | | | | | | |
| Basic | Triethanolamine | | | | | | 10 | | | | |
| compound | 1-Methylimidazole | | | | | 11.7 | | 8.1 | | 6.4 | 3.4 |
| | Triethylamine | | | | | | 4.6 | | 9.4 | | |
| | Pentamethyldiethylenetri- | | 4.8 | 5.6 | | | | | | | |
| | amine | | | | | | | | | | |
| | N-ethyldiethanolamine | 7 | | 2.9 | 7 | 18.7 | | | | | 8.9 |
| Additional | Water | | | | | 1.63 | | 1 | | 1.3 | 0.6 |
| additive | Ethylene glycol | 15 | | | 15 | | | | | | |
| | PVP K30 | 0.2 | | | 0.2 | | | | | | |
| Molar ratio (basic group/ | | 0.67 | 0.52 | 0.55 | 1.13 | 1.13 | 0.96 | 0.61 | 0.4 | 0.4 | 1.31 |
| reducing organic substance) | | | | | | | | | | | |
| DTG maximum peak temperature (°C) | | 194 | | | 194 | | 130 | 135 | 123 | 117 | 136 |
| Viscosity (Pa · s) | | 121 | 89.7 | 11 | 166 | 0.3 | 239 | 394 | 66 | 403 | 245 |
| Storage | 1 week under 5 °C condition | ∘ | ∘ | ∘ | ∘ | ∘ | ∘ | ∘ | x | x | ∘ |
| stability | 1 week under 25 °C condition | ∘ | ∘ | ∘ | ∘ | ∘ | ∘ | ∘ | x | x | ∘ |
| Fillability | Patterning interval: 40 μm | ∘ | ∘ | ∘ | ∘ | ∘ | x | x | ∘ | x | x |
| | Patterning interval: 20 μm | x | ∘ | ∘ | x | ∘ | x | x | ∘ | x | x |

### (4) Liquid Composition

The reducing organic substance, the basic compound, the coordinating organic compound, the solvent, and the metal particles used for preparing a liquid composition are as follows.

### Reducing Organic Substance

Formic acid: reagent available from FUJIFILM Wako Pure Chemical Corporation (boiling point: 101 °C)
Oxalic acid: reagent available from FUJIFILM Wako Pure Chemical Corporation (boiling point: 365 °C)

### Basic Compound

MDETA: N-methyldiethanolamine, reagent available from FUJIFILM Wako Pure Chemical Corporation
PMDTA: pentamethyldiethylenetriamine, reagent available from Tokyo Chemical Industry Co., Ltd.
DMAMPZ: 1-(2-dimethylaminoethyl)-4-methylpiperazine, reagent available from Tokyo Chemical Industry Co., Ltd.
DMDA: N,N-dimethyldodecylamine, reagent available from Tokyo Chemical Industry Co., Ltd.

### Coordinating Organic Compound

Acetic acid: reagent available from FUJIFILM Wako Pure Chemical Corporation (boiling point: 118 °C)
nHxA: n-hexanoic acid, reagent available from Higashiyama Film Co., Ltd. (boiling point: 205 °C)
nOcA: n-octanoic acid, reagent available from Tokyo Chemical Industry Co., Ltd. (boiling point: 237 °C) Solvent
TEC: triethyl citrate, reagent available from Tokyo Chemical Industry Co., Ltd.
EtOH: ethanol, reagent available from FUJIFILM Wako Pure Chemical Corporation

### Preparation of Liquid Composition Sample

The reducing organic substances, the basic compounds, the coordinating organic compounds, and the solvents were weighed and blended in a screw tube to achieve the contents shown in Tables 2 and 3, and then stirred for 1 minute at 2000 rpm using a planetary centrifugal mixer (product name “Awatori Rentaro”, available from Thinky Corporation), thereby preparing liquid composition samples 1 to 22 used for evaluation of oxide film removal performance, deposition of metal nanoparticles, electrical conductivity, and bondability.

TABLE 2

| | | Liquid | Liquid | Liquid | Liquid | Liquid | Liquid | Liquid | Liquid | Liquid | Liquid | Liquid | Liquid |
|---|---|---|---|---|---|---|---|---|---|---|---|---|---|
| | | Compo- | Compo- | Compo- | Compo- | Compo- | Compo- | Compo- | Compo- | Compo- | Compo- | Compo- | Compo- |
| | | sition | sition | sition | sition | sition | sition | sition | sition | sition | sition | sition | sition |
| (wt. %) | | 1 | 2 | 3 | 4 | 5 | 6 | 7 | 8 | 9 | 10 | 11 | 12 |
| Reducing | Formic | 1 | 1 | 1 | 1 | 1 | 1 | 1 | 1 | 1 | 1 | 1 | 1 |
| organic | acid | | | | | | | | | | | | |
| substance | | | | | | | | | | | | | |
| Basic | MDETA | 1.5 | | 1.5 | | | | | | | | | |
| compound | PMDTA | | 0.75 | | 0.75 | | 1.3 | | 0.62 | | | | |
| | DMAMPZ | | | | | 0.75 | | 1.3 | 0.62 | 1.3 | 1.3 | | |
| | DMDA | | | 0.2 | 0.2 | 0.2 | 0.2 | 0.2 | 0.2 | 0.2 | 0.2 | | |
| Coordinating | nOcA | | | | 0.4 | 0.4 | 0.4 | 0.4 | 0.4 | | | | 0.4 |
| organic | nHxA | | | | | | | | | 0.4 | | | |
| compound | Acetic | | | | | | | | | | 0.4 | | |
| | acid | | | | | | | | | | | | |
| Molar ratio (basic | | 0.6 | 0.6 | 0.64 | 0.64 | 0.64 | 1.04 | 1.04 | 1.04 | 1.04 | 1.04 | | |
| group/acidic group) | | | | | | | | | | | | | |
| Molar ratio | | | | | 0.21 | 0.21 | 0.13 | 0.13 | 0.13 | 0.16 | 0.31 | | |
| (coordinating/basic) | | | | | | | | | | | | | |
| Solvent | TEC | | | | | | 2.9 | 2.9 | 2.84 | 2.9 | 2.7 | | |

TABLE 3

| | | Liquid | Liquid | Liquid | Liquid | Liquid | Liquid | Liquid | Liquid | Liquid | Liquid |
|---|---|---|---|---|---|---|---|---|---|---|---|
| | | Compo- | Compo- | Compo- | Compo- | Compo- | Compo- | Compo- | Compo- | Compo- | Compo- |
| | | sition | sition | sition | sition | sition | sition | sition | sition | sition | sition |
| (wt. %) | | 13 | 14 | 15 | 16 | 17 | 18 | 19 | 20 | 21 | 22 |
| Reducing | Formic | 1 | 1 | 1 | 1 | 1 | 1 | 1 | 1 | | 1 |
| organic | acid | | | | | | | | | | |
| substance | Oxalic | | | | | | | 0.2 | | | |
| | acid | | | | | | | | | | |
| Basic | MDETA | 1.3 | 2.6 | 1.5 | | 1 | 1.3 | 1.3 | 2 | 1 | |
| compound | PMDTA | | | | 0.75 | | | | | | |
| | DMDA | | | | | 0.2 | | | | | |
| Molar ratio (basic | | 0.5 | 1 | 0.6 | 0.6 | 0.44 | 0.6 | 0.5 | 2 | | |
| group/acidic group) | | | | | | | | | | | |
| Solvent | EtOH | | | | | | 2.3 | 2.5 | | | |

### Examples 7 to 10 and Comparative Examples 7 and 8

The “oxide film removal performance on surface of copper foil” was evaluated using the liquid composition samples.

### Surface Treatment of Copper Foil

A copper foil (trade name “C1020P”) having a thickness of 100 μm was cut into a square shape (5 cm×5 cm), and heated at 200 °C for 10 minutes in the atmospheric air using a hotplate, thereby producing a test piece of an oxidized copper foil having an oxide film on a surface thereof.

The oxidized copper foil test piece in which two drops (about 40 mg) of the liquid composition sample were added dropwise on a central portion of the oxidized copper foil using a dropper was placed on a hotplate in a glove compartment in a nitrogen atmosphere (oxygen concentration: 100 ppm or less), heated from normal temperature (25 °C) to 150 °C at a temperature rising rate of 10 °C/min, held for 5 minutes, further heated to 200 °C at a temperature rising rate of 10 °C/min, held for 10 minutes, then naturally cooled to normal temperature (25 °C), and, after cooling, washed with methanol to produce a liquid composition-treated copper foil.

### Measurement of Thickness of Oxide Film on Copper Foil Surface

The thickness of an oxide film formed of an oxide or the like on the surface of the treated copper foil was measured by a continuous electrochemical method using an oxide film/metal film thickness measuring machine (product name “QC-100”, available from ECI TECHNOLOGY). The measurement conditions are as follows. A total value of the thicknesses of cuprous (I) oxide, copper (II) oxide, and copper sulfide obtained from the measurement results was defined as the thickness of the oxide film. The measurement was performed on a place where the liquid droplets remained to the end when the liquid composition was volatilized. When the measurement was not possible within the measurement time of 10 minutes, the thickness was defined as 100 Å or more. The liquid composition samples used and the evaluation results are shown in Table 3. The copper oxide thickness of the copper foil before the oxidization was 35 Å.
Measurement range (gasket size): φ 3.2 mm
Current value: 30 μA/cm²
Measurement time: up to 10 minutes

### Evaluation Criteria for Oxide Film Removal Performance

The oxide film removal performance on a surface of the copper foil was evaluated according to the following criteria.
1 (Good): 30 Å or less
2 (Acceptable): more than 30 Å and less than 100 Å
3 (Poor): 100 Å or more

TABLE 4

| | Example | | | | Comparative Example | |
|---|---|---|---|---|---|---|
| | 7 | 8 | 9 | 10 | 7 | 8 |
| Liquid composition | 1 | 2 | 3 | 4 | 11 | 12 |
| Oxide film thickness (Å) | 13 | 20 | 5 | 50 | >100 | >100 |
| Evaluation | 1 | 1 | 1 | 2 | 3 | 3 |

Examples 7 to 10 showed that the oxide film was satisfactorily removed by the treatment using the liquid composition of the present disclosure (evaluation: 1 and 2). On the other hand, Comparative Examples 7 and 8 in which no basic compound was contained showed that the oxide film removal performance was poor (evaluation: 3).

### Examples 11 to 20 and Comparative Example 9

The “deposition of metal nanoparticles on surface of copper foil” was evaluated. For the evaluation, the liquid composition-treated copper foil produced in the evaluation of the “oxide film removal performance on surface of copper foil” was used.

### Surface of Copper Foil

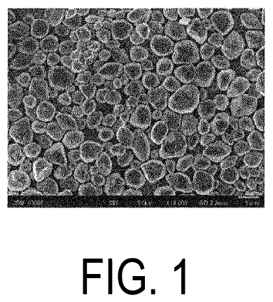

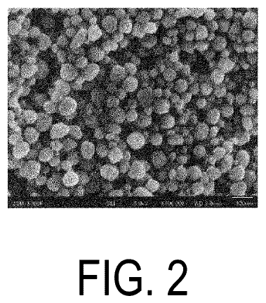

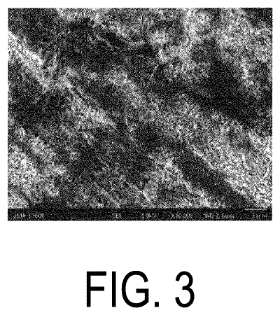

The presence or absence of deposition of metal nanoparticles was confirmed by electron microscope observation, and when deposition of metal nanoparticles was observed, the particle sizes of 100 particles were measured and a mean value was calculated to obtain a number average particle size. The liquid composition samples used and the evaluation results are shown in Table 9. In addition, FIGS. 1 to 3 show electron micrograph images of Example 16, Example 17, and Comparative Example 9, respectively (the lower right bar in FIG. 1: 1 μm, the lower right bar in FIG. 2: 100 nm, and the lower right bar in FIG. 3: 1 μm).

TABLE 5

| | | | | | | | | | | | Comparative |
|---|---|---|---|---|---|---|---|---|---|---|---|
| | Example | | | | | | | | | | Example |
| | 11 | 12 | 13 | 14 | 15 | 16 | 17 | 18 | 19 | 20 | 9 |
| Liquid | 1 | 2 | 3 | 4 | 5 | 6 | 7 | 8 | 9 | 10 | 12 |
| composition | | | | | | | | | | | |
| Number average | >1000 | >1000 | >1000 | 20 | 50 | 25 | 50 | 36 | 63 | 500 | — |
| particle size (nm) | | | | | | | | | | | |

The symbol “-” in the column of particle size indicates that no particle shape deformation was observed on the surface.

Examples 11 to 20 showed that copper nanoparticles were deposited, and Examples 11 to 13 in which no coordinating organic compounds were added showed that copper particles of more than 1000 nm were deposited. Examples 14 to 20 in which the coordinating organic compounds were added showed that copper particles of from 20 to 500 nm were deposited. Addition of the coordinating organic compound can suppress coarsening during nanoparticle production and increase the influence of surface diffusion during bonding, and thus the metal members are easily bonded even at a lower temperature. On the other hand, Comparative Example 9 in which no basic compound was contained showed that no copper particles were deposited.

### Examples 21 to 28 and Comparative Examples 10 and 11

The “electrical conductivity” of a sintered body of a copper particle aggregate was evaluated using the liquid composition samples.

### Production of Copper Particle Aggregate

After mixing 10.5 g of formic acid, 10.5 g of nOcA, 2.6 g of PMDTA, 10.9 g of MDEtA and 13.5 g of DMDA, 0.5 g of a polyvinyl butyral resin (trade name “S-LEC B BL-1”, available from Sekisui Chemical Co., Ltd.) as a binder resin was further added and uniformly mixed to obtain a dispersion solvent for a copper paste.

Using a planetary centrifugal mixer (product name “ARE-310” available from Thinky Corporation), 10 g of the copper particles CH-0200L1, 10 g of the copper particles CT-0500, and 2.4 g of the dispersion solvent for a copper paste were stirred and mixed at 2000 rpm for 3 minutes to obtain a copper paste.

The copper paste was molded and heated at 200 °C for 5 minutes in a nitrogen atmosphere to produce an aggregate of copper particles (strip shape, 50 mm long, 10 mm wide, 20 μm thick). The aggregate of copper particles was not sintered and did not exhibit electrical conductivity.

The liquid composition sample was applied to the produced aggregate of copper particles, the aggregate was fired at 200 °C for 30 minutes in a nitrogen atmosphere to obtain a sintered body, and the volume resistivity of the obtained sintered body was measured using a resistivity meter (product name “Loresta GP MCP-T610”, available from Mitsubishi Chemical Analytech Co., Ltd.). A smaller value of volume resistivity indicates more excellent “electrical conductivity”. The liquid composition samples used and the evaluation results are shown in Table 6.

### Evaluation Criteria for Electrical Conductivity

The electrical conductivity was evaluated according to the following criteria.
1 (Good): volume resistivity of less than 20 μΩ·cm
2 (Acceptable): volume resistivity of 20 μΩ·cm or more and less than 100 μΩ·cm
3 (Poor): volume resistivity of 100 μΩ·cm or more

TABLE 6

| | | | | | | | | | Comparative | |
|---|---|---|---|---|---|---|---|---|---|---|
| | Example | | | | | | | | Example | |
| | 21 | 22 | 23 | 24 | 25 | 26 | 27 | 28 | 10 | 11 |
| Liquid composition | 13 | 14 | 15 | 16 | 17 | 18 | 19 | 20 | 21 | 22 |
| Volume | 12 | 15 | 13 | 9 | 10 | 11 | 8 | 25 | 130 | — |
| resistivity (μΩ · cm) | | | | | | | | | | |
| Electrical | 1 | 1 | 1 | 1 | 1 | 1 | 1 | 2 | 3 | 3 |
| conductivity | | | | | | | | | | |
| evaluation | | | | | | | | | | |

The symbol “-” in the column of particle size indicates that no current flowed and that no measurement value was obtained.

Examples 21 to 28 showed that the volume resistivity was low and that good electrical conductivity was obtained (evaluation: 1 and 2). On the other hand, Comparative Examples 10 and 11 in which the reducing organic substance or the basic compound was not contained showed that the volume resistivity was high and that the electrical conductivity was poor.

### Example 29, Bonding Between Microelectrodes

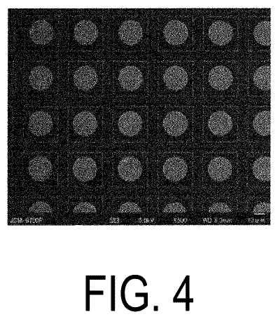

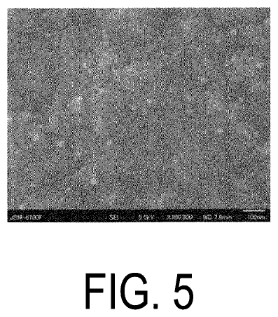

An Si chip with copper bumps (trade name: “WALTS-TEG CC 40”, 10 mm×10 mm, available from Walts Corporation) having a pattern in which 28224 (168×168) copper bumps (height: 15 μm, 22 μm φ) were arranged at intervals of 40 μm in a range of 10 mm×10 mm, and an Si interposer (trade name “WALTS-TEG IP40”, available from Walts Corporation) provided with copper pads corresponding to the pattern were used. FIG. 4 shows an electron micrograph image of the arrangement pattern of the copper bumps, and FIG. 5 shows an electron micrograph image of the surfaces of the copper bump portions (the lower right bar in FIG. 4: 10 μm, the lower right bar in FIG. 5: 100 nm).

The surfaces of the copper bumps were oxidized by heating the Si chip with the copper bumps at 200 °C for 5 minutes in the atmospheric air using a hotplate.

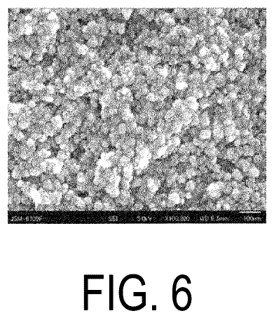

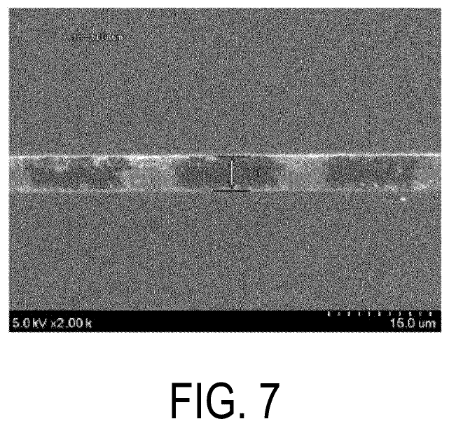

The Si chip with the oxidized copper bumps was applied with 5 μL of the liquid composition sample 7 using a micropipette, then placed on a hotplate in a glove compartment with a nitrogen atmosphere (oxygen concentration: 100 ppm or less), heated from normal temperature (25 °C) to 150 °C at a temperature rising rate of 10 °C/min, held for 5 minutes, further heated to 200 °C at a temperature rising rate of 10 °C/min, held for 10 minutes, and then naturally cooled to normal temperature (25 °C). After cooling, the Si chip was washed with methanol to obtain a liquid composition-treated Si chip. FIG. 7 shows an electron micrograph image of the surfaces of the copper bump portions of the liquid composition-treated Si chip (the lower right bar in FIG. 6: 100 nm). Copper nanoparticles were deposited on the surfaces of the copper bumps.

Using a micropipette, 5 μL of the liquid composition sample 19 was applied onto the Si interposer to obtain a liquid composition-coated Si interposer. The liquid composition-coated Si interposer and the liquid composition-treated Si chip were stacked in such a manner that the positions of the copper pads and the copper bumps corresponded to each other, and bonded by heating at 200 °C for 10 minutes under a load of 1 MPa in a nitrogen atmosphere using a flip chip bonder (product name “T-3000-PRO-HF”, available from Dr. TRESKY).

The bonding strength of the bonded body was measured using a universal bond tester (product name “Die Shear Tester SERIES 4000”, available from Nordson DAGE, Inc.). The bonding strength was 25 MPa, which indicated sufficient strength and excellent bondability.

From the above results, the bonding temperature of the copper pillar could be lowered to 200 °C by the liquid composition according to the sixth embodiment for assisting in bonding of pillars for semiconductor connection to each other. That is, it was found that the process conditions of a high temperature of from 300 to 400 °C and a high pressure required for copper-copper bonding of the pillars formed by copper plating are not required, and that a semiconductor device can be produced with a reduction in warpage of the base material and a small influence on other members.

### Polymer Hybrid Bonding

### Example 30

The photosensitive resin composition (R-1) according to Example 1 was applied onto an Si wafer with an oxide film by spin coating, and prebaked at 120 °C for 5 minutes. Thereafter, photolithography was performed under the conditions described in Example 1 to produce a substrate for forming copper pillars, which was patterned at intervals of 20 μm. The copper paste of Example 4 was coated onto the substrate for forming copper pillars using an applicator, and then the temperature was raised to 150 °C at 5 °C/min in a nitrogen atmosphere, held for 5 minutes, then raised to 200 °C at 5 °C/min, and held for 10 minutes to form copper pillars. After the formation of the copper pillars, planarization was performed by CMP to produce a chip with copper pillars. Two of the chips with copper pillars were prepared, and mounted with a flip chip bonder, with the copper pillars of the chips being in contact with each other and the photosensitive resin composition on the two chips being in contact with each other, and were heated and bonded at 250 °C for 10 minutes while applying a load of 1.6 MPa in a nitrogen atmosphere, thereby producing a bonded body.

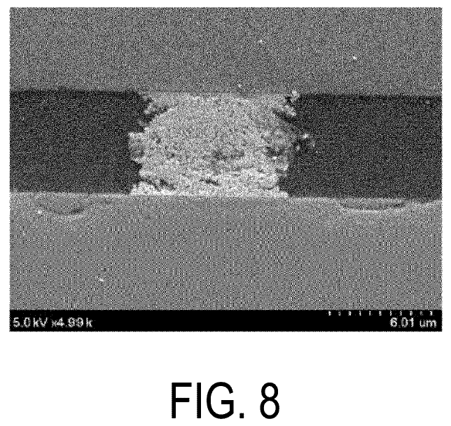

The bonding strength of the bonded body, when measured using a universal bond tester, was 16 MPa. The method for producing a semiconductor device according to the fifth embodiment showed that the bondability between the bonded bodies was more excellent. FIGS. 7 and 8 show images of the cross section of the bonded body of Example 30 observed with a scanning electron microscope at a magnification of 2000 times (FIG. 7) or 5000 times (FIG. 8).

### Example 31

On an Si wafer with an oxide film on which copper pillars were formed at intervals of 20 μm, DSM-AcHEt (available from Daicel Corporation) was applied by spin coating, and then baked at 100 °C for 5 minutes. On the baked wafer, R2MX1 (available from Daicel Corporation) was applied by spin coating, and then heated at 80 °C for 4 minutes and further heated at 100 °C for 2 minutes to remove the solvent. Further, baking was performed at 130 °C for 20 minutes, followed by planarization by CMP, thereby producing a chip with copper pillars. The liquid composition sample 6 was applied to the surface of the chip with copper pillars to produce a liquid composition-treated chip. Two of the chips were prepared, and mounted with a flip chip bonder, with the copper pillars of the chips being in contact with each other and the photosensitive resin composition on the two chips being in contact with each other, and were heated and bonded at 200 °C for 10 minutes while applying a load of 1.6 MPa in a nitrogen atmosphere, thereby producing a bonded body.

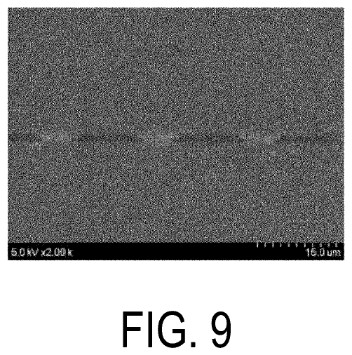

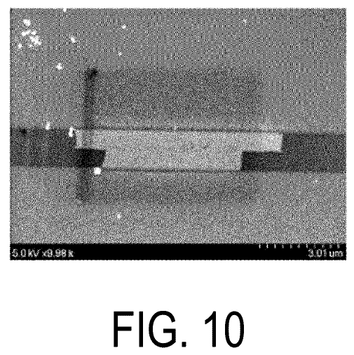

FIGS. 9 and 10 show images of the cross section of the bonded body of Example 31 observed with a scanning electron microscope at a magnification of 2000 times (FIG. 9) or 10000 times (FIG. 10). From the cross-sectional SEM observation of the bonded body, it was confirmed that the copper pillars were bonded to each other, and further, the temperature of the copper-copper bonding could be lowered to 200 °C. It was found that the method for producing a semiconductor device according to the ninth embodiment can bond the bonded bodies to each other in fewer steps and can perform copper-copper bonding at a lower temperature.

### INDUSTRIAL APPLICABILITY

The method for producing a semiconductor device according to the present embodiments can perform bonding of metal pillars with a narrower pitch in fewer steps than in the related art, and thus can be suitably used for a method for producing a semiconductor device or the like, and has industrial applicability.

The polymer of the present embodiments and the photosensitive resin composition containing the same can enable patterning at a narrower pitch, can be suitably used in a method for producing a semiconductor device or the like, and have industrial applicability.

The copper paste of the present embodiments can reduce the number of steps for forming a copper pillar as compared with the related art, can lower the bonding temperature, can be suitably used in a method for producing a semiconductor device or the like, and has industrial applicability.

The liquid composition of the present embodiments can lower the bonding temperature as compared with the related art, can be suitably used in a method for producing a semiconductor device or the like, and has industrial applicability.

1. A method for producing a semiconductor device, the method comprising:
preparing a structure, including
forming a resin layer on a substrate or a semiconductor chip using a resin composition, and
patterning the resin layer to form a patterned resin layer including an opening; and
bonding two or more of the structures using the patterned resin layer.

2. The method for producing a semiconductor device according to claim 1, wherein the resin composition is a photosensitive resin composition, and the patterning is performed by exposure and development.

3. The method for producing a semiconductor device according to claim 1, wherein a pitch of the adjacent openings is 80 μm or less.

4. The method for producing a semiconductor device according to claim 1, wherein the preparation includes producing a metal pillar in the opening.

5. The method for producing a semiconductor device according to claim 4, wherein the producing a metal pillar includes filling the opening with a copper paste.

6. The method for producing a semiconductor device according to claim 4, further comprising planarizing a surface where the metal pillar and a pattern of the patterned resin layer exist, prior to the bonding.

7. The method for producing a semiconductor device according to claim 4, wherein the bonding includes bonding two or more of the structures at a temperature of 200 °C or higher and 250 °C or lower with the metal pillars of the respective structures overlapping each other.

8. The method for producing a semiconductor device according to claim 4, wherein the bonding includes bonding two or more of the structures at a temperature of lower than 200 °C with the metal pillars of the respective structures overlapping each other.

9. The method for producing a semiconductor device according to claim 4, further comprising applying a liquid composition to a bonding portion of the metal pillar before the bonding.

10. The method for producing a semiconductor device according to claim 9, wherein the liquid composition contains a reducing organic substance, a basic compound, and a coordinating organic compound excluding a compound included in the basic compound, and the coordinating organic compound has a boiling point higher than that of the reducing organic substance.

11. The method for producing a semiconductor device according to claim 1, wherein the resin layer is formed using a polymer (A) containing monomer units (A1) and (A2):
a monomer unit (A1): a monomer having an alkali-soluble group,
a monomer unit (A2): an aromatic (meth)acrylate having a phenolic hydroxyl group.

12. A polymer (A) for producing the resin composition in the method for producing a semiconductor device described in claim 1, the polymer (A) comprising monomer units (A1) and (A2):
a monomer unit (A1): a monomer having an alkali-soluble group,
a monomer unit (A2): an aromatic (meth)acrylate having a phenolic hydroxyl group.

13. The polymer (A) according to claim 12, further comprising a monomer unit (A3): an N-substituted maleimide compound.

14. The polymer (A) according to claim 12, further comprising a monomer unit (A4): an alkyl (meth)acrylate having an alkyl group with 2 or more carbon atoms.

15. The polymer (A) according to claim 12, wherein a proportion of the monomer unit (A1) to a total amount (100 mol %) of all the monomer units constituting the polymer (A) is from 5 to 50 mol %.

16. A photosensitive resin composition for the method for producing a semiconductor device described in claim 1, the photosensitive resin composition comprising:
a polymer (A) containing monomer units (A1) and (A2):
a monomer unit (A1): a monomer having an alkali-soluble group,
a monomer unit (A2): an aromatic (meth)acrylate having a phenolic hydroxyl group;
a photopolymerization initiator (B); and
a solvent (C).

17. A method for producing a semiconductor device, the method comprising:
a first step of applying a photosensitive resin composition on a base material or a semiconductor chip;
a second step of patterning the photosensitive resin composition by photolithography with a maximum interval width being 80 μm or less;
a third step of filling an opening formed by the patterning with a copper paste and drying the copper paste to form a copper pillar;
a fourth step of planarizing a surface having the copper pillar and the patterning without peeling off the photosensitive resin composition; preparing a set of structures obtained through the first step to the fourth step;
a fifth step of applying a liquid composition to the planarized surface of at least one of the set of structures;
a sixth step of stacking the set of structures with the copper pillars being in contact with each other; and
a seventh step of heating the set of structures at 200 °C or lower in an inert atmosphere.

18. The method for producing a semiconductor device according to claim 17, wherein the photosensitive resin composition contains: a polymer (A) containing monomer units (A1) and (A2):
a monomer unit (A1): a monomer having an alkali-soluble group,
a monomer unit (A2): an aromatic (meth)acrylate having a phenolic hydroxyl group;
a photopolymerization initiator (B); and
a solvent (C).
